(19) United States
(12) Patent Application Publication
(10) Pub. No.: US 2025/0364475 A1
(43) Pub. Date: Nov. 27, 2025

(54) ANISOTROPICALLY CONDUCTIVE MEMBER AND BONDED BODY

(71) Applicant: FUJIFILM CORPORATION, Tokyo (JP)

(72) Inventor: Shunji Kurooka, Shizuoka (JP)

(21) Appl. No.: 19/297,822

(22) Filed: Aug. 12, 2025

Related U.S. Application Data
(63) Continuation of application No. PCT/JP2024/036615, filed on Oct. 15, 2024.

(30) Foreign Application Priority Data
Mar. 28, 2024 (JP) 2024-053707

(51) Int. Cl. H01L 23/00

(52) U.S. Cl. CPC H01L 24/29; H01L 24/32; H01L 2224/29017; H01L 2224/29076; H01L 2224/29124; H01L 2224/29144; H01L 2224/29147; H01L 2224/32145

(57) ABSTRACT

Provided are an anisotropically conductive member and a bonded body, in which buckling of a conduction path is suppressed. The anisotropically conductive member includes an insulating base material having electrical insulating properties, and a plurality of conduction paths that penetrate in a thickness direction of the insulating base material, are provided in a state of being electrically insulated from each other, and have a protruding portion which protrudes from at least one surface of the insulating base material. In a cross section of the insulating base material in the thickness direction, the surface of the insulating base material, from which the protruding portion of the conduction path protrudes, has a plurality of apex portions and a plurality of contact portions in which a plurality of protruding portions are in contact with the insulating base material. An arithmetic mean distance between the plurality of contact portions and the plurality of apex portions in the thickness direction is 2 nm to 200 nm.

### CROSS-REFERENCE TO RELATED APPLICATIONS

This application is a Continuation of PCT International Application No. PCT/JP2024/036615 filed on Oct. 15, 2024, which claims priority under 35 U.S.C. § 119(a) to Japanese Patent Application No. 2024-053707 filed on Mar. 28, 2024. The above applications are hereby expressly incorporated by reference, in their entirety, into the present application.

### BACKGROUND OF THE INVENTION

### 1. Field of the Invention

The present invention relates to an anisotropically conductive member and a bonded body, which include a plurality of conduction paths that penetrate in a thickness direction of an insulating base material and include a protruding portion which protrudes from at least one surface of the insulating base material, and in particular, relates to an anisotropically conductive member and a bonded body, in which a surface of the insulating base material on which the protruding portion protrudes has a plurality of apex portions and a plurality of contact portions in which the protruding portion is in contact with the insulating base material.

### 2. Description of the Related Art

There is an anisotropically conductive member having a conduction path in which a plurality of through-holes provided in an insulating base material are filled with a conductive substance such as metal.

In a case where the anisotropically conductive member is inserted between an electronic component such as a semiconductor element and a circuit board and is simply pressurized, an electrical connection between the electronic component and the circuit board can be obtained, so that the anisotropically conductive bonding member has been widely used as an electrical connecting member of the electronic component or the like such as a semiconductor element or used as a testing connector thereof for carrying out a functional test.

In particular, an electronic component such as a semiconductor element is significantly downsized. In a method of directly connecting a wiring board such as a wire bonding in the related art, flip chip bonding, thermocompression bonding, and the like, stability of electrical connection of the electronic component may not be sufficiently guaranteed, and thus, an anisotropically conductive member has been attracting attention as an electronic connection member.

As the anisotropically conductive member, for example, JP2018-037509A discloses an anisotropically conductive bonding member including an insulating base material consisting of an inorganic material, a plurality of conduction paths consisting of conductive members, and a resin layer provided on the entire surface of the insulating base material. The conduction path penetrates the insulating base material in a thickness direction in a state of being insulated from each other. The conduction path has a protruding portion which is parallel to each other and protrudes from the surface of the insulating base material, and an end part of the protruding portion is embedded in the resin layer.

### SUMMARY OF THE INVENTION

In a case where the above-described anisotropically conductive bonding member of JP2018-037509A is used as an electronic connection member, a conduction path of the anisotropically conductive bonding member and an electrode or the like of a semiconductor element to be connected are bonded to each other. During the bonding, a protruding portion of the conduction path, which protrudes from a surface of the insulating base material, may buckle.

In a case where the protruding portion of the conduction path buckles during the bonding, there is a possibility that the conduction path and the electrode or the like of the semiconductor element may not be sufficiently bonded to each other, and there is a possibility that a sufficient bonding strength may not be obtained. Therefore, it is desired to avoid the buckling of the conduction path.

An object of the present invention is to provide an anisotropically conductive member and a bonded body, in which buckling of a conduction path is suppressed.

In order to achieve the above-described object, the invention [1] is an anisotropically conductive member including an insulating base material having electrical insulating properties, and a plurality of conduction paths that penetrate in a thickness direction of the insulating base material, are provided in a state of being electrically insulated from each other, and have a protruding portion which protrudes from at least one surface of the insulating base material, in which, in a cross section of the insulating base material in the thickness direction, the surface of the insulating base material, from which the protruding portion of the conduction path protrudes, has a plurality of apex portions and a plurality of contact portions in which a plurality of protruding portions are in contact with the insulating base material, and an arithmetic mean distance between the plurality of contact portions and the plurality of apex portions in the thickness direction is 2 nm to 200 nm.

The invention [2] is the anisotropically conductive member according to the invention [1], in which the conduction path is composed of Cu, Au, or Al.

The invention [3] is the anisotropically conductive member according to the invention [1] or [2], in which, in a case where a diameter of the protruding portion is denoted by d and a length of the protruding portion in the thickness direction of the insulating base material is denoted by h, d/h is 0.1 to 20.

The invention [4] is the anisotropically conductive member according to any one of the inventions [1] to [3], in which a length of the protruding portion in the thickness direction of the insulating base material is 6 to 6,000 nm.

The invention [5] is a bonded body including an anisotropically conductive member and a member to be bonded, in which the anisotropically conductive member and the member to be bonded are bonded to each other, a resin fills a space between the anisotropically conductive member and the member to be bonded, the anisotropically conductive member includes an insulating base material having electrical insulating properties, and a plurality of conduction paths that penetrate in a thickness direction of the insulating base material, are provided in a state of being electrically insulated from each other, and have a protruding portion which protrudes from at least one surface of the insulating base material, in a cross section of the insulating base material in the thickness direction, the surface of the insulating base material, from which the protruding portion of the conduction path protrudes, has a plurality of apex portions and a plurality of contact portions in which a plurality of protruding portions are in contact with the insulating base material, and an arithmetic mean distance between the plurality of contact portions and the plurality of apex portions in the thickness direction is 2 nm to 200 nm.

The invention [6] is the bonded body according to the invention [5], in which the member to be bonded has a metal layer and a resin layer, and the metal layer is exposed from the resin layer.

The invention [7] is the bonded body according to the invention [5], in which the member to be bonded has a plurality of metal layers, and at least one of the plurality of metal layers has a different height.

The invention [8] is the bonded body according to the invention [6], in which the member to be bonded has a bonding surface provided with a plurality of metal layers, and an area of the bonding surface is larger than an area of the surface of the anisotropically conductive member, from which the protruding portion protrudes.

According to the present invention, it is possible to provide an anisotropically conductive member and a bonded body, in which buckling of a conduction path is suppressed.

### BRIEF DESCRIPTION OF THE DRAWINGS

FIG. 1 is a schematic cross-sectional view showing an example of the anisotropically conductive member according to the embodiment of the present invention.

FIG. 2 is a schematic plan view showing the example of the anisotropically conductive member according to the embodiment of the present invention.

FIG. 3 is a schematic cross-sectional view showing a part of the example of the anisotropically conductive member according to the embodiment of the present invention in an enlarged form.

FIG. 4 is a schematic cross-sectional view showing a first example of the bonded body according to the embodiment of the present invention.

FIG. 5 is a schematic cross-sectional view showing a part of the first example of the bonded body according to the embodiment of the present invention in an enlarged form.

FIG. 6 is a schematic cross-sectional view showing a method for manufacturing the first example of the bonded body according to the embodiment of the present invention.

FIG. 7 is a schematic cross-sectional view showing a part of a second example of the bonded body according to the embodiment of the present invention in an enlarged form.

FIG. 8 is a schematic cross-sectional view showing one step of an example of the method for manufacturing the anisotropically conductive member according to the embodiment of the present invention.

FIG. 9 is a schematic cross-sectional view showing one step of the example of the method for manufacturing the anisotropically conductive member according to the embodiment of the present invention.

FIG. 10 is a schematic cross-sectional view showing one step of the example of the method for manufacturing the anisotropically conductive member according to the embodiment of the present invention.

FIG. 11 is a schematic cross-sectional view showing one step of the example of the method for manufacturing the anisotropically conductive member according to the embodiment of the present invention.

FIG. 12 is a schematic cross-sectional view showing one step of the example of the method for manufacturing the anisotropically conductive member according to the embodiment of the present invention.

FIG. 13 is a schematic cross-sectional view showing one step of the example of the method for manufacturing the anisotropically conductive member according to the embodiment of the present invention.

FIG. 14 is a schematic cross-sectional view showing one step of the example of the method for manufacturing the anisotropically conductive member according to the embodiment of the present invention.

### DESCRIPTION OF THE PREFERRED EMBODIMENTS

Hereinafter, the anisotropically conductive member and bonded body according to the embodiments of the present invention will be described in detail based on suitable embodiments shown in the accompanying drawings.

The drawings described below are exemplary for describing the present invention and are simplified or exaggerated for describing the present invention. Therefore, the present invention is not limited to the drawings described below.

In the following, “to” indicating the numerical range includes numerical values described on both sides. For example, in a case where ϵ is a numerical value ϵ_{α} to a numerical value ϵ_{β}, the range of ϵ is a range including the numerical value ϵ_{α} and the numerical value ϵ_{β}, and in mathematical symbols, ϵ_{α}≤ϵ≤ϵ_{β}.

Unless otherwise specified, a term “parallel” or “orthogonal” includes an error range generally allowed in the relevant technical field.

Unless otherwise specified, a temperature, a time, and a pressure include error ranges generally allowed in the relevant technical field.

In addition, a term “same” includes an error range is generally allowed in the relevant technical field. In addition, a term “entire surface” or the like includes an error range is generally allowed in the relevant technical field.

Hereinafter, the anisotropically conductive member and the bonded body will be specifically described.

### [Example of Anisotropically Conductive Member]

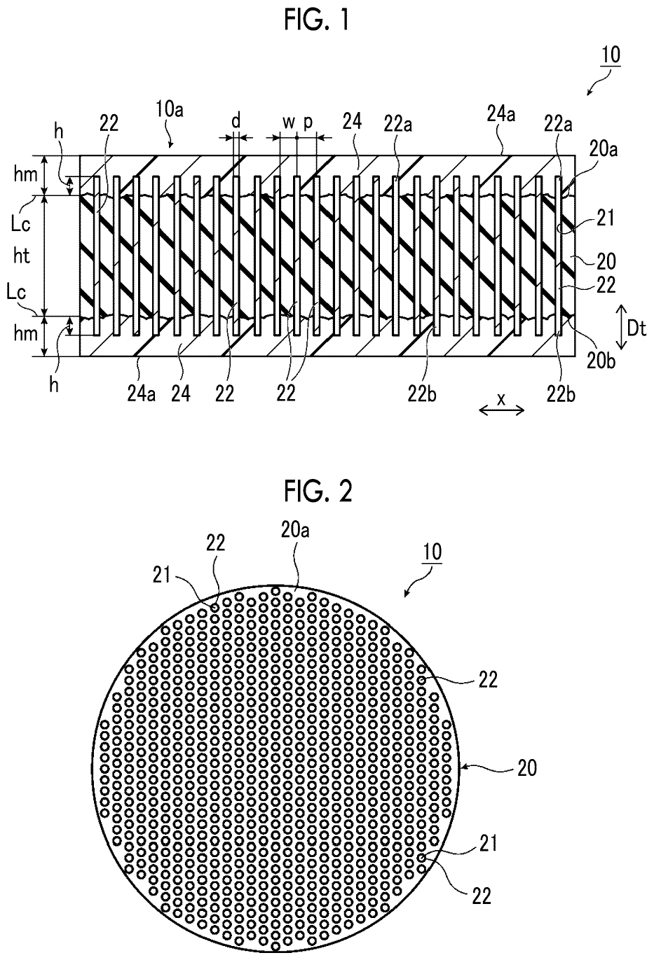

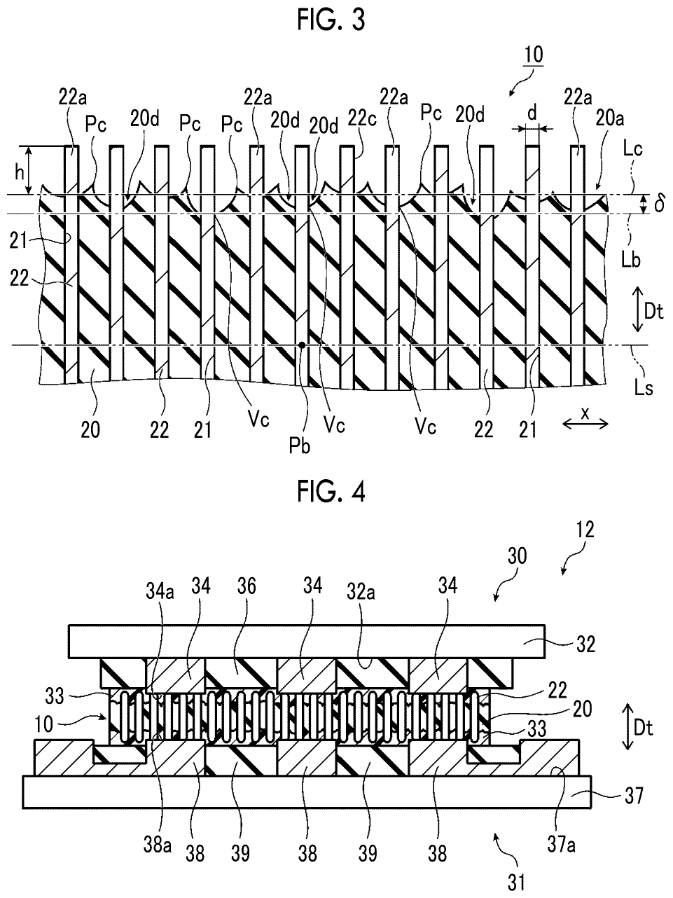

FIG. 1 is a schematic cross-sectional view showing an example of the anisotropically conductive member according to the embodiment of the present invention. FIG. 2 is a schematic plan view showing the example of the anisotropically conductive member according to the embodiment of the present invention. FIG. 3 is a schematic cross-sectional view showing a part of the example of the anisotropically conductive member according to the embodiment of the present invention in an enlarged form.

FIGS. 1 and 3 show a cross section of an insulating base material 20 in a thickness direction Dt. In addition, FIG. 2 is a plan view of FIG. 1 as viewed from a front surface 20a side of an insulating base material 20, shows a state in which a resin layer 24 is not present.

An anisotropically conductive member 10 shown in FIG. 1 includes an insulating base material 20 having electrical insulating properties, and a plurality of conduction paths 22 that penetrate in a thickness direction Dt of the insulating base material 20, are provided in a state of being electrically insulated from each other, and have a protruding portion which protrudes from at least one surface. In addition, the resin layer 24 which covers at least one surface of the insulating base material 20 is provided. The anisotropically conductive member 10 has conductivity in the thickness direction Dt of the insulating base material 20.

In the anisotropically conductive member 10, the resin layer 24 is not necessarily required, and a configuration in which the resin layer 24 is not provided may be adopted.

The plurality of conduction paths 22 are provided on the insulating base material 20 in a state of being electrically insulated from each other. In this case, for example, the insulating base material 20 has a plurality of pores 21 penetrating in the thickness direction Dt. The conduction path 22 is provided in a plurality of pores 21. The conduction path 22 protrudes from a front surface 20a of the insulating base material 20. In addition, the conduction path 22 protrudes from a back surface 20b of the insulating base material 20.

The conduction path 22 may protrude from one surface of the insulating base material 20 in the thickness direction Dt. For example, the resin layer 24 is provided on the surface of the insulating base material 20, from which the conduction path 22 protrudes. The resin layer 24 covers a protruding portion 22a of the conduction path 22, and the protruding portion 22a is embedded in the resin layer 24. In addition, the resin layer 24 covers a protruding portion 22b of the conduction path 22, and the protruding portion 22b is embedded in the resin layer 24.

The insulating base material 20 is composed of, for example, an anodized film. The anodized film is formed by, for example, anodizing a valve metal.

The front surface 20a of the insulating base material 20 and a back surface 20b of the insulating base material 20 are surfaces facing each other in the thickness direction Dt of the insulating base material 20.

The anisotropically conductive member 10 has anisotropic conductivity and has conductivity in the thickness direction Dt as described above, but has low conductivity in a direction x parallel to a front surface 20a of the insulating base material 20. The direction x is a direction orthogonal to the thickness direction Dt.

As shown in FIG. 2, the anisotropically conductive member 10 has, for example, a circular outer shape. The outer shape and size of the anisotropically conductive member 10 are appropriately determined according to the application and the like, and the outer shape may be, for example, a quadrangular shape.

For example, the anisotropically conductive member 10 is bonded in a state in which the resin layer 24 is not present or in a state in which nothing is present on a surface 24a even in a case where the resin layer 24 is present.

As shown in FIG. 3, the front surface 20a of the insulating base material 20 has a configuration of unevenness instead of a flat surface. A plurality of recessed portions 20d are present on the front surface 20a of the insulating base material 20. A recessed portion 20d is provided for each conduction path 22. The recessed portion 20d is disposed to surround the conduction path 22 with the conduction path 22 as a center.

In a cross section of the insulating base material 20 shown in FIG. 3 in the thickness direction Dt, the surface of the insulating base material 20, from which the protruding portion 22a protrudes, that is, the front surface 20a in FIG. 3 has a plurality of apex portions Pc and a plurality of contact portions Vc.

The apex portion Pc is a high portion of the surface of the insulating base material 20 on the protruding portion 22a side in the cross section of the insulating base material 20 in the thickness direction Dt. The apex portion Pc is, for example, a boundary portion between the adjacent recessed portions 20d.

The contact portion Vc is a portion in which the plurality of protruding portions 22a are in contact with the insulating base material 20 in the cross section of the insulating base material 20 in the thickness direction Dt. The contact portion Vc is provided at an end part of the protruding portion 22a on the insulating base material 20 side. More specifically, the contact portion Vc is provided at a bottom portion of the recessed portion 20d on the back surface 20b side of the insulating base material 20.

In the anisotropically conductive member 10, an arithmetic mean distance in the thickness direction Dt between the plurality of contact portions Vc and the plurality of apex portions Pc is 2 nm to 200 nm, preferably 2 nm to 150 nm, more preferably 20 nm to 100 nm, and still more preferably 20 nm to 60 nm.

Since the anisotropically conductive member 10 has a configuration of the front surface 20a of the insulating base material 20, from which the protruding portion 22a protrudes, and the arithmetic mean distance δ in the thickness direction Dt between the plurality of contact portions Vc and the plurality of apex portions Pc is set to 2 nm to 200 nm, in a case where a force acts on the protruding portion 22a in a direction parallel to the thickness direction Dt, the protruding portion 22a is allowed to bend more in the direction x than a case where the front surface 20a of the insulating base material 20 is a flat surface, and the arithmetic mean distance is less than 2 nm. That is, in the recessed portion 20d, the protruding portion 22a is allowed to have a side surface 22c displaced more in the direction x than in the case of the flat surface. As a result, buckling of the protruding portion 22a is suppressed, so that a sufficient bonding strength can be obtained for a connection target, and sufficient conductivity can be secured with respect to the connection target. Furthermore, occurrence of a short circuit is suppressed without contact with the adjacent protruding portion.

In addition, in a case where the force acts on the protruding portion 22a in the direction parallel to the thickness direction Dt and the protruding portion 22a is deformed such that a diameter thereof increases in the direction x, the protruding portion 22a is allowed to be deformed such that a diameter thereof increases in the direction x, as compared with a case where the front surface 20a of the insulating base material 20 is a flat surface. In this case, it is allowed that the diameter of the protruding portion 22a increases in the recessed portion 20d in the direction x. Therefore, the buckling of the protruding portion 22a is suppressed. Even in this case, a sufficient bonding strength can be obtained for the connection target, sufficient conductivity can be secured with respect to the connection target, and the occurrence of a short circuit is suppressed without contact with the adjacent protruding portion.

In a case where the above-described arithmetic mean distance δ is less than 2 nm, when a force acts on the protruding portion 22a in a direction parallel to the thickness direction Dt, the protruding portion 22a can be displaced in the direction x by a small amount, and thus the protruding portion 22a buckles. Therefore, a sufficient bonding strength cannot be obtained for the connection target. In a case where the protruding portion 22a buckles, the protruding portion 22a may come into contact with the adjacent protruding portion, and sufficient conductivity cannot be secured with respect to the connection target.

In a case where the above-described arithmetic mean distance δ is more than 200 nm, the end part on the insulating base material 20 side is closer to the center of the insulating base material 20 in the thickness direction Dt, the recessed portion 20d becomes deeper, and the protruding portion 22a becomes substantially longer. Therefore, the protruding portion is likely to buckle. In a case where a force acts on the protruding portion 22a in a direction parallel to the thickness direction Dt, the protruding portion buckles and comes into contact with the adjacent protruding portion, and thus sufficient conductivity cannot be secured with respect to the connection target.

The above-described arithmetic mean distance δ can be obtained, for example, as follows.

First, the cross section of the anisotropically conductive member 10 in the thickness direction Dt of the insulating base material 20 is exposed by machining the anisotropically conductive member 10 using a focused ion beam (FIB).

For the cross section of the insulating base material 20 in the thickness direction Dt, an image is acquired at a magnification of 150k using a field emission scanning electron microscope (FE-SEM).

In the captured image, a reference point Pb is set at any position on the back surface 20b side of the insulating base material 20, opposite to the front surface 20a. A reference line Ls parallel to the direction x passing through the reference point Pb is set.

In the captured image, 10 apex portions Pc are selected in descending order from the reference line Ls among the points corresponding to the apex portions Pc. In addition, among the points corresponding to the contact portions Vc, 10 contact portions Vc are selected in ascending order from the reference line Ls.

In the captured image, a distance from the reference line Ls is obtained for each of the 10 selected points corresponding to the apex portions Pc. An average value of the 10 distances between the 10 points corresponding to the apex portions Pc and the reference line Ls is obtained by the least squares method. The average value obtained by the least squares method is shown as a point on the captured image. A line Lc parallel to the direction x passing through a point indicating the average value of the apex portion Pc is obtained. A plane including the parallel line Lc is an average plane of the front surface 20a of the insulating base material 20. The average plane of the front surface 20a of the insulating base material 20 serves as a reference for the length of the protruding portion 22a.

In the captured image, a distance from the reference line Ls is obtained for each of the 10 selected points corresponding to the contact portions Vc. An average value of the 10 distances between the 10 points corresponding to the contact portions Vc and the reference line Ls is obtained by the least squares method. The average value obtained by the least squares method is shown as a point on the captured image. A line Lb parallel to the direction x passing through a point indicating the average value of the contact portion Vc is obtained. A plane including the parallel line Lb is an average plane of the contact portion Vc.

The arithmetic mean distance δ is an absolute value of a difference between the average value of the apex portion Pc obtained by the least squares method and the average value of the contact portion Vc obtained by the least squares method. That is, the arithmetic mean distance δ is a distance between the parallel line Lc and the parallel line Lb in the thickness direction Dt. Therefore, the arithmetic mean distance δ is obtained by obtaining the distance between the parallel line Lc and the parallel line Lb in the thickness direction Dt.

Although not shown in detail, the back surface 20b of the insulating base material 20 also has the same configuration as the front surface 20a of the insulating base material 20 shown in FIG. 3. The arithmetic mean distance δ is also determined for the back surface 20b of the insulating base material 20 in the same manner as the front surface 20a of the insulating base material 20 described above.

### [First Example of Bonded Body]

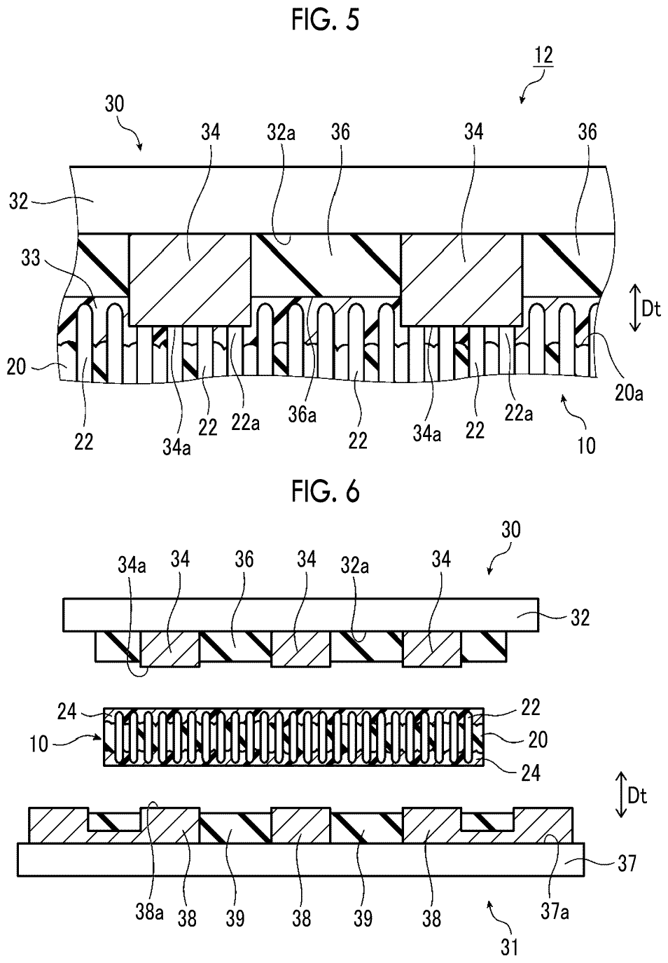

FIG. 4 is a schematic cross-sectional view showing a first example of the bonded body according to the embodiment of the present invention. FIG. 5 is a schematic cross-sectional view showing a part of a first example of the bonded body according to the embodiment of the present invention in an enlarged form.

In FIGS. 4 and 5, components having the same constitution as that of the anisotropically conductive member 10 shown in FIGS. 1 to 3 are designated by the same reference numerals, and detailed description thereof will not be repeated.

A bonded body 12 shown in FIG. 4 is obtained by bonding the anisotropically conductive member 10 to a semiconductor element 30 and a semiconductor element 31 as a member to be bonded. The member to be bonded is a connection target.

In the bonded body 12, a resin fills a space between the anisotropically conductive member 10 and the member to be bonded.

In the semiconductor element 30, for example, three electrodes 34 and an insulating layer 36 which prevents conduction between the three electrodes 34 are provided on a surface 32a of an element substrate 32. The three electrodes 34 have the same height from the surface 32a of the element substrate 32.

In addition, in the semiconductor element 31, for example, three electrodes 38 and an insulating layer 39 which prevents conduction between the three electrodes 38 are provided on a surface 37a of an element substrate 37. The three electrodes 38 have the same height from the surface 37a of the element substrate 37.

The electrode 34 and the electrode 38 are bonded to the conduction path 22 of the anisotropically conductive member 10. For example, as shown in FIG. 5, the surface 34a of the electrode 34 and the protruding portion 22a of the conduction path 22 are bonded in a state of being in contact with each other. In this case, the protruding portion 22a of the conduction path 22 is pressed by the surface 34a of the electrode 34 to deform the protruding portion 22a, but the buckling of the protruding portion 22a is suppressed as described above. Therefore, in the bonded body 12, a sufficient bonding strength can be obtained for the semiconductor element 30 and the semiconductor element 31. In addition, since the buckling of the protruding portion 22a is suppressed, sufficient conductivity can be secured with respect to the connection target, and furthermore, the occurrence of a short circuit is suppressed without contact with the adjacent protruding portion.

The electrodes 34 and 38 are used for exchanging signals with the outside or for receiving and giving a voltage or a current, and are made of, for example, copper or solder. An electrode made of solder is also referred to as a solder bump.

A configuration of the insulating layer 39 is not particularly limited as long as it can prevent conduction between electrodes, and the insulating layer 39 can be configured with a known insulating layer used in a semiconductor element. The insulating layer 39 is composed of, for example, a silicon oxide film (SiO₂), a silicon nitride film (Si₃N₄), a phospho silicate glass (PSG) film, a boron phospho silicate glass (BPSG) film, or a spin on glass (SOG) film.

A resin layer 33 is formed by, for example, the resin layer 24 of the anisotropically conductive member 10. In this case, the anisotropically conductive member 10 having the resin layer 24 is used for the bonding.

In addition, the resin layer 33 can also be formed by a resin layer (not shown) provided on the surface 34a of the electrode 34 of the semiconductor element 30 and a resin layer (not shown) provided on the surface 38a of the electrode 38 of the semiconductor element 31.

In addition, after the conduction path 22 of the anisotropically conductive member 10 is bonded to the electrodes 34 and 38, a resin agent can be supplied between the conduction path 22 and the electrode 34 and between the conduction path 22 and the electrode 38 to form the resin layer 33.

### (Method for Manufacturing First Example of Bonded Body)

The bonded body 12 shown in FIG. 4 is bonded, for example, as shown in FIG. 6.

FIG. 6 is a schematic cross-sectional view showing a method for manufacturing the first example of the bonded body according to the embodiment of the present invention.

In FIG. 6, components having the same constitution as that of the bonded body 12 shown in FIGS. 4 and 5 are designated by the same reference numerals, and detailed description thereof will not be repeated.

As shown in FIG. 6, the semiconductor element 30 and the semiconductor element 31 are disposed with the anisotropically conductive member 10 interposed therebetween. In this case, for example, registration is performed using alignment marks (not shown) provided on the semiconductor elements 30 and 31 and the anisotropically conductive member 10, respectively. The registration using the alignment marks is not particularly limited as long as an image or a reflection image of the alignment marks can be acquired and the position information of the alignment marks can be obtained, and a known registration method can be appropriately used.

As shown in FIG. 6, the anisotropically conductive member 10 is provided with the resin layer 24, and the resin layer 24 forms the resin layer 33 of the bonded body 12 shown in FIG. 4.

Next, the semiconductor element 30 and the anisotropically conductive member 10 are bonded to each other, and the semiconductor element 31 and the anisotropically conductive member 10 are bonded to each other. In this manner, the bonded body 12 shown in FIG. 4 can be manufactured.

The bonding of the anisotropically conductive member 10 to the semiconductor element 30 and the bonding the anisotropically conductive member 10 to the semiconductor element 31 described above is a bonding step. In the bonding step, a temporary bonding may be carried out, for example, in a temporarily bonded state under predetermined conditions, but the temporary bonding may be omitted. The bonding in the bonding step is also referred to as main bonding.

The temporary bonding refers to fixing the semiconductor elements 30 and 31 and the anisotropically conductive member 10 in a registered state.

Temperature conditions in the temporary bonding process are not particularly limited, but are preferably 0° C. to 300° C., more preferably 10° C. to 200° C., and particularly preferably normal temperature (23° C.) to 100° C.

Similarly, pressurization conditions in the temporary bonding process is not particularly limited, but are preferably 10 MPa or less, more preferably 5 MPa or less, and particularly preferably 1 MPa or less.

Temperature conditions in the main bonding are not particularly limited, but the temperature is preferably a temperature higher than the temperature of the temporary bonding. Specifically, the temperature is more preferably 120° C. to 350° C. and particularly preferably 200° C. to 300° C.

In addition, pressurization conditions in the main bonding are not particularly limited, but are preferably 30 MPa or less, and more preferably 0.1 to 20 MPa.

In addition, a time of the main bonding is not particularly limited, but is preferably 1 second to 60 minutes and more preferably 5 seconds to 10 minutes.

By performing the main bonding under the above-described conditions, the protruding portion 22a of the conduction path 22 and the surface 34a of the electrode 34 are bonded to each other, and the protruding portion 22b of the conduction path 22 and the surface 38a of the electrode 38 are bonded to each other. In this case, as described above, both the protruding portion 22a and the protruding portion 22b of the conduction path 22 are suppressed from buckling, and for example, the protruding portions 22a and 22b are also suppressed from falling down and coming into contact with the adjacent protruding portions 22a and 22b. As a result, sufficient bonding strength is secured for the connection target, sufficient conductivity is secured with respect to the connection target, and the occurrence of a short circuit is also suppressed.

### [Second Example of Bonded Body]

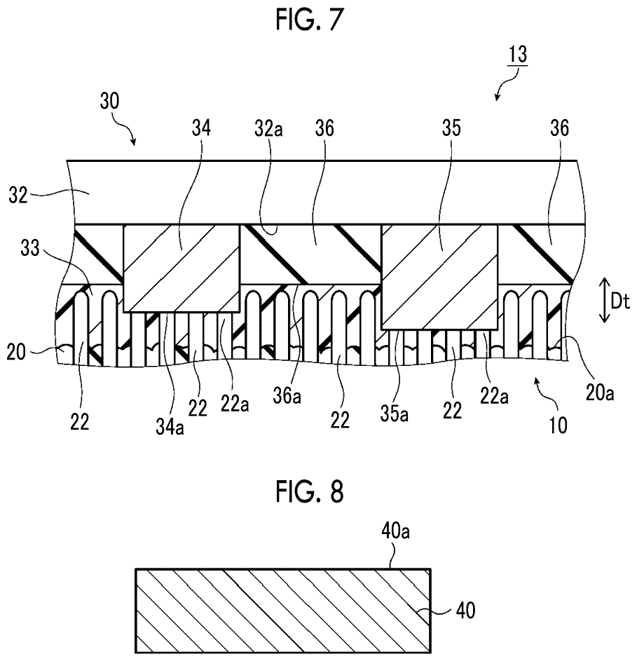

FIG. 7 is a schematic cross-sectional view showing a part of a second example of the bonded body according to the embodiment of the present invention in an enlarged form.

In FIG. 7, components having the same constitution as that of the bonded body 12 shown in FIGS. 4 and 5 are designated by the same reference numerals, and detailed description thereof will not be repeated.

A bonded body 13 shown in FIG. 7 is different from the bonded body 12 shown in FIGS. 4 and 5 in that the semiconductor element 30 has electrodes 35 having different heights, and the other configurations are the same as those of the bonded body 12 shown in FIGS. 4 and 5. The electrode 35 has a height higher than that of the electrode 34.

In the bonded body 13, the electrode 34 and the electrode 35 having a higher height are bonded to the anisotropically conductive member 10. In the bonded body 13, the electrode 35 is closer to the anisotropically conductive member 10 than the electrode 34, and thus the protruding portion 22a of the conduction path 22 is largely deformed. Even in this case, the buckling of the protruding portion 22a is suppressed as described above. Even in the configuration in which the semiconductor element 30 has the relatively high electrode 35 as described above, a sufficient bonding strength can be obtained for the semiconductor element 30 and the semiconductor element 31. In addition, since the buckling of the protruding portion 22a is suppressed, sufficient conductivity is ensured, and the occurrence of a short circuit is also suppressed.

In the bonded body 12 and the bonded body 13, it is preferable that the member to be bonded has a bonding surface provided with a plurality of metal layers, and an area of the bonding surface is larger than an area of the surface of the anisotropically conductive member, from which the protruding portion protrudes.

Here, in the above-described semiconductor elements 30 and 31, a plurality of electrodes are provided on the surface of the element substrate, and the surface of the element substrate corresponds to the bonding surface. It is preferable that the area of the surface of the element substrate is larger than the areas of the front surface 20a and the back surface 20b of the insulating base material 20, from which the protruding portions 22a and 22b of the anisotropically conductive member 10 protrude.

Hereinafter, the configuration of the anisotropically conductive member will be described in more detail.

### (Insulating Base Material)

The insulating base material 20 has electrical insulating properties and maintains a plurality of conduction paths 22, which are formed of a conductive substance, in a state of being electrically insulated from each other. The insulating base material 20 has a plurality of pores 21 in which the conduction path 22 is formed. A formulation and the like of the insulating base material will be described later.

A length of the insulating base material 20 in the thickness direction Dt, that is, a thickness ht of the insulating base material 20 is preferably in a range of 1 to 1,000 μm, more preferably in a range of 5 to 500 μm, still more preferably in a range of 10 to 300 μm, and particularly preferably 10 μm or more and 30 μm or less. In a case where the thickness of the insulating base material 20 is within the range, the handleability of the insulating base material 20 is improved.

The thickness of the insulating base material is obtained for each of the front surface 20a side and the back surface 20b side of the insulating base material 20 with respect to the above-described line Lc. A distance between the line Lc on the front surface 20a side and the line Lc on the back surface 20b side in the thickness direction Dt is defined as the thickness of the insulating base material.

The insulating base material 20 is not particularly limited as long as it consists of, for example, an inorganic material and has an electrical resistivity (approximately 10¹⁴ Ω·cm) similar to that of an insulating base material constituting the conventionally known anisotropic conductive film or the like.

The “consisting of an inorganic material” is a definition for distinguishing from a polymer material constituting a resin layer, which will be described later; and is not a definition limited to an insulating base material consisting of only an inorganic material, but is a definition in which an inorganic material is a main component (50% by mass or more).

Examples of the insulating base material include a metal oxide base material, a metal nitride base material, a glass base material, a ceramic base material such as silicon carbide and silicon nitride, a carbon base material such as diamond-like carbon, a polyimide base material, and a composite material thereof. In addition to the above, the insulating base material may be a film formed of an inorganic material containing 50% by mass or more of a ceramic material or a carbon material, on an organic material having through-holes.

In the insulating base material, micropores having a desired average opening diameter are formed as through-holes. From the viewpoint of easily forming the conduction path, the insulating base material is preferably a metal oxide base material and more preferably an anodized film of a valve metal.

Here, specific examples of the valve metal include aluminum, tantalum, niobium, titanium, hafnium, zirconium, zinc, tungsten, bismuth, and antimony. Among these, an aluminum anodized film (base material) is preferable since it has favorable dimensional stability and is relatively inexpensive. Accordingly, it is preferable to form an anodized film which is an insulating base material and to manufacture the anisotropically conductive member using an aluminum substrate.

A thickness of the anodized film is the thickness of the insulating base material 20 described above.

### <Aluminum Substrate>

The aluminum substrate for forming the anodized film which is an insulating base material is not particularly limited, and specific examples thereof include a pure aluminum plate; an alloy plate having aluminum as a main component and including a trace amount of foreign elements; a substrate obtained by vapor-depositing high-purity aluminum on low-purity aluminum (for example, a recycled material); a substrate obtained by covering a surface of a silicon wafer, quartz, glass, or the like with high-purity aluminum by a method such as vapor deposition and sputtering; and a resin substrate laminated with aluminum.

A surface of the aluminum substrate, on which the anodized film is provided by an anodization treatment step, preferably has an aluminum purity of 99.5% by mass or more, more preferably 99.9% by mass or more, and still more preferably 99.99% by mass or more. In a case where the aluminum purity is within the above-described range, regularity of the arrangement of the through-holes is sufficient. The micropores are pores.

The aluminum substrate is not particularly limited as long as the anodized film can be formed, and for example, Japanese Industrial Standards (JIS) 1050 Material is used.

In addition, it is preferable that the surface of the aluminum substrate on one side to be subjected to the anodization treatment step is subjected to a heat treatment, a degreasing treatment, and a mirror finishing treatment in advance.

Here, with regard to the heat treatment, the degreasing treatment, and the mirror

finishing treatment, the same treatments as those described in paragraphs to of JP2008-270158A can be performed.

The mirror finishing treatment before the anodization treatment is, for example, electropolishing, and an electropolishing liquid containing phosphoric acid is used for the electropolishing.

### <Average Diameter of Pores>

An average diameter of the pores 21 is preferably 1 μm or less, more preferably 5 to 500 nm, still more preferably 20 to 400 nm, even more preferably 40 to 200 nm, and most preferably 50 to 100 nm. In a case where the average diameter d of the pores 21 is 1 μm or less and is within the above-described range, it is possible to obtain the conduction path 22 having the above-described average diameter.

The average diameter of the pores 21 can be obtained, for example, as follows. First, the front surface of the insulating base material 20 is imaged from directly above at a magnification of 100 to 10,000 times with a scanning electron microscope (SEM) to obtain a captured image. At least 20 pores of which a periphery is connected in an annular shape are extracted from the captured image, diameters thereof are measured to obtain opening diameters, and an average value of the opening diameters is calculated as the average diameter of the pores.

For the magnification, a magnification in the above-described range can be appropriately selected so that the captured image from which 20 or more pores can be extracted is obtained. In addition, the opening diameter is measured as the maximum value of the distance between the end parts of the pore portions. That is, since the shape of the opening portion of the pores is not limited to the substantially circular shape, in a case where the shape of the opening portion is non-circular, the maximum value of the distance between the end parts of the pore portions is defined as the opening diameter. Therefore, for example, even in a case of pores having a shape in which two or more pores are integrated, the pores are regarded as one pore, and the maximum value of the distance between the end parts of the pore portions is regarded as the opening diameter.

### <Conduction Path>

The plurality of conduction paths 22 are provided in the insulating base material 20, for example, in the anodized film as described above in a state of being electrically insulated from each other.

Each of the plurality of conduction paths 22 is a columnar conductor having electrical conductivity, and is composed of a conductive substance. The conductive substance is not particularly limited, and examples thereof include a metal. Specific suitable examples of the metal include gold (Au), silver (Ag), copper (Cu), aluminum (Al), magnesium (Mg), nickel (Ni), zinc (Zn), and cobalt (Co). From the viewpoint of electrical conductivity and formation by a plating method, as the conductive substance, copper (Cu), gold (Au), aluminum (Al), nickel (Ni), or cobalt (Co) is preferable, copper (Cu), gold (Au), or aluminum (Al) is more preferable, and copper (Cu) is still more preferable.

Since the metal is more excellent in ductility and the like and is easily deformed than the oxide conductor, and is easily deformed even in compression during bonding, it is preferable that the conduction path is composed of a metal.

An average diameter d of the conduction path 22 is preferably 1 μm or less, more preferably 5 to 500 nm, still more preferably 20 to 400 nm, even more preferably 40 to 200 nm, and most preferably 50 to 100 nm.

A density of the conduction paths 22 is preferably 20,000 pieces/mm² or more, more preferably 2,000,000 pieces/mm² or more, still more preferably 10,000,000 pieces/mm² or more, particularly preferably 50,000,000 pieces/mm² or more, and most preferably 100,000,000 pieces/mm² or more.

Furthermore, a center-to-center distance p of adjacent conduction paths 22 is preferably 20 nm to 500 nm, more preferably 40 nm to 200 nm, and still more preferably 50 nm to 140 nm.

Regarding the conduction path 22, an interval w between adjacent protruding portions (see FIG. 1) is 20 nm to 200 nm, preferably 40 nm to 100 nm. In a case where the interval between the adjacent protruding portions adjacent is within the above-described range, the interval of the conduction path 22 can be maintained even on the front surface 20a or the back surface 20b of the insulating base material 20 of the conduction path 22. As a result, during the bonding, short-circuit of the conduction path 22 is suppressed, and thus reliability during the bonding is increased.

The average diameter of the conduction path can be obtained, for example, as follows. First, the front surface of the insulating base material is imaged from directly above at a magnification of 100 to 10,000 times with a scanning electron microscope to obtain a captured image. At least 20 conduction paths of which a periphery is connected in an annular shape are extracted from the captured image, diameters thereof are measured to obtain opening diameters, and an average value of the opening diameters is calculated as the average diameter of the conduction paths.

For the magnification, a magnification in the above-described range can be appropriately selected so that the captured image from which 20 or more conduction paths can be extracted is obtained. In addition, in a case where the shape of the opening portion is a non-circular shape, the maximum value of the distance between the end parts of the conduction path portions is defined as the opening diameter. Therefore, for example, even in a case of conduction paths having a shape in which two or more conduction paths are integrated, the conduction paths are regarded as one pore, and the maximum value of the distance between the end parts of the conduction path portions is regarded as the opening diameter. The average diameter d of the conduction path 22 is the same as the average diameter of the protruding portion.

In a case where the shape of the conduction path 22 on the front surface 20a side of the insulating base material 20 is not a circle, the average diameter of the insulating base material 20 on the front surface 20a side is an equivalent circle diameter. In addition, in a case where the shape of the conduction path 22 on the back surface 20b side of the insulating base material 20 is not a circle, the average diameter of the insulating base material 20 on the back surface 20b side is an equivalent circle diameter.

In addition, the average diameter d of the conduction path 22 on the front surface 20a side of the insulating base material 20 can be measured from a front surface image of the front surface 20a of the insulating base material 20 obtained by a scanning electron microscope. The average diameter d of the conduction path 22 on the back surface 20b side of the insulating base material 20 can be measured from a back surface image of the back surface 20b of the insulating base material 20 obtained by a scanning electron microscope.

In a case where the front surface image and the back surface image are used as described above, and it is difficult to measure the average diameter due to the protruding portion, the protruding portion is removed by dissolution or the like. As a result, the pores appear. The opening diameter of a plurality of pores in the front surface image in this state can be measured, and the average opening diameter of the pores in the front surface can be used instead of the average diameter on the front surface side. In addition, similarly, the opening diameter of a plurality of pores in the back surface image in this state can be measured, and the average opening diameter of the pores in the back surface can be used instead of the average diameter on the back surface side.

The above-described average opening diameter of the pores can be measured, for example, as follows. First, in the above-described front surface image, 20 pieces of the pores are selected, and diameters of portions corresponding to the openings of the pores are measured for the 20 pieces of the pores. An average value of the diameters of the measured pores corresponding to the openings is calculated, and this average value is defined as the average opening diameter of the pores on the front surface side.

In addition, in the above-described back surface image, 20 pieces of the pores are selected, and diameters of portions corresponding to the openings of the pores are measured for the 20 pieces of the pores. An average value of the diameters of the measured pores corresponding to the openings is calculated, and this average value is defined as the average opening diameter of the pores on the back surface side.

In the captured image of the insulating base material 20 obtained as described above, a center position (not shown) of a specified conduction path is further specified as the center-to-center distance p between the adjacent conduction paths 22. A distance between center positions of the adjacent conduction paths is obtained at 10 locations. An average value thereof is defined as the center-to-center distance p of adjacent conduction paths 22. The center position is a center position of a region corresponding to the conduction path 22 in the above-described captured image. In the captured image, a known image analysis method is used to calculate the center position of the region.

### «Protruding Portion»

The protruding portion is a part of the conduction path, and has a columnar shape. It is preferable that the protruding portion has a columnar shape since a contact area with the member to be bonded can be increased.

A length h of the protruding portion 22a in the thickness direction Dt of the insulating base material 20 and a length h of the protruding portion 22b in the thickness direction Dt of the insulating base material 20 are preferably 2 nm to 6,000 nm and more preferably 5 nm to 3,000 nm. In a case where the length h is 10 nm to 1,000 nm, the member to be bonded can be satisfactorily bonded.

In the length h of the protruding portion 22a and the length h of the protruding portion 22b, the average plane of the front surface 20a in the insulating base material 20 described above is used as a reference for the length of the protruding portion 22a.

In a case where the above-described length h of the protruding portion 22a and the above-described protruding portion 22b in the thickness direction Dt of the insulating base material 20 is 2 nm to 6,000 nm, bump height distribution followability of the bump on the side of the object to be bonded is favorable, and height accuracy of the bump surface on the side of the object to be bonded is not required.

For the length h of the protruding portion 22a and the length h of the protruding portion 22b, an image is acquired at a magnification of 100,000 times using a field emission scanning electron microscope (FE-SEM) for a cross section of the insulating base material 20 in the thickness direction Dt. In the captured image, the line Lc on the front surface side of the insulating base material and the line Lc on the back surface side of the insulating base material are obtained as described above.

Next, 10 protruding portions 22a are selected in the captured image. A point corresponding to the apex portion of the selected 10 protruding portions 22a is specified. A distance in the thickness direction Dt of the insulating base material 20 between the point corresponding to the apex portion of the specified protruding portion 22a and the line Lc on the front surface side of the insulating base material is obtained for each of the 10 protruding portions 22a. An average value of the distances of the points corresponding to the apex portions of the 10 protruding portions 22a is obtained. The average value is defined as the length h of the protruding portion 22a.

In addition, 10 protruding portions 22b are selected in the captured image. A point corresponding to the apex portion of the selected 10 protruding portions 22b is specified. A distance in the thickness direction Dt of the insulating base material 20 between the point corresponding to the apex portion of the specified protruding portion 22b and the line Lc on the back surface side of the insulating base material is obtained for each of the 10 protruding portions 22b. An average value of the distances of the points corresponding to the apex portions of the 10 protruding portions 22b is obtained. The average value is defined as the length h of the protruding portion 22b.

In a case where a diameter of the protruding portion is denoted by d and a length of the protruding portion in the thickness direction of the insulating base material is denoted by h, it is preferable that d/h representing an aspect ratio is 0.1 to 20. In a case where the aspect ratio d/h is 0.1 to 20, the bonded body can be stably manufactured, and the bonding strength is excellent.

### [Resin Layer]

The resin layer covers at least one surface of the front surface or the back surface of the insulating base material as described above, and protects the insulating base material and the conduction path. In a case where the conduction path has a protruding portion, the protruding portion is embedded in the resin layer. That is, the resin layer covers an end part of the conduction path which protrudes from the insulating base material, and protects the protruding portion.

In order to exhibit the above-described function, it is preferable that the resin layer exhibits fluidity in a temperature range of 50° C. to 200° C. and is cured at 200° C. or higher. The resin layer is, for example, a thermoplastic layer composed of a thermoplastic resin or the like, and the resin layer will be described in detail later.

An average thickness hm of the resin layer 24 is preferably 10 μm or less, more preferably 5 μm or less, and still more preferably 1 μm or less. In a case where the average thickness hm of the resin layer 24 is 10 μm or less as described above, the protruding portion of the conduction path 22 can be protected, and the effect of filling the periphery of the electrode during the bonding to a connection target such as a semiconductor device can be sufficiently exhibited.

The average thickness hm of the resin layer 24 is the average distance from the front surface 20a of the insulating base material 20 or the average distance from the back surface 20b of the insulating base material 20. For the above-described average thickness hm of the resin layer 24, the resin layer is cut in the thickness direction Dt of the anisotropically conductive member 10, and an image of the cut cross section is acquired with a scanning electron microscope. In the captured image, the line Lc on the front surface 20a side of the insulating base material 20 and the line Lc on the back surface side of the insulating base material are obtained as described above.

Next, in the captured image, 10 locations corresponding to the surface 24a of the resin layer 24 are selected. A distance between the selected location and the line Lc on the front surface 20a side of the insulating base material 20 is obtained for each of the 10 locations. An average value of the distances of the 10 locations is obtained. The average value is defined as the average thickness hm of the resin layer 24 on the front surface 20a side of the insulating base material 20.

Furthermore, for the resin layer on the back surface 20b side of the insulating base material 20, 10 locations corresponding to the surface 24a of the resin layer 24 are selected in the captured image. A distance between the selected location and the line Lc on the back surface 20b side of the insulating base material 20 is obtained for each of the 10 locations. An average value of the distances of the 10 locations is obtained. The average value is defined as the average thickness hm of the resin layer 24 on the back surface 20b side of the insulating base material 20.

As the resin layer, a formulation shown below can also be used. Hereinafter, the formulation of the resin layer will be described. For example, the resin layer contains a polymer material, and may contain an antioxidant material.

Specific examples of a resin material constituting the resin layer include thermoplastic resins such as an ethylene-based copolymer, a polyamide resin, a polyester resin, a polyurethane resin, a polyolefin-based resin, an acrylic resin, an acrylonitrile-based resin, and a cellulose-based resin. As the resin material constituting the resin layer, polyacrylonitrile can also be used. Examples of a resin material constituting the resin layer include an epoxy resin, a phenol resin, a polyimide resin, a melamine resin, and an isocyanate-based resin. Among these, from the viewpoint of further improving insulating reliability and having excellent chemical resistance, it is preferable to use a polyimide resin and/or an epoxy resin.

As the resin layer, in addition to the above, for example, a resin layer containing a main composition containing an acrylic polymer, an acrylic monomer, and a maleimide compound, which is described in WO2022/163260A, can be used.

### ((Member to be Bonded to Anisotropically Conductive Member))

In a case where the anisotropically conductive member is used as the electronic connection member, the member to be bonded, which is the connection target, is, for example, a semiconductor element, or an element having an electrode or an element region. Examples of the element having an electrode include a semiconductor element which exhibits a specific function by itself, but also include a case in which a plurality of elements are gathered to exhibit the specific function. Furthermore, it also includes a wiring member which only transmit electrical signals, and also includes a printed wiring board or the like which has an electrode.

The element region is a region in which various element configuration circuits and the like, for functioning as an electronic element, are formed. The element region includes, for example, a region where a memory circuit of a flash memory or the like, and a logic circuit such as a microprocessor, a field-programmable gate array (FPGA), or the like are formed and a region where a communication module such as a wireless tag, and a wiring line are formed. In addition to the above, a micro electro mechanical system (MEMS) may be formed in the element region. Examples of the MEMS include a sensor, an actuator, and an antenna. The sensor includes, for example, various sensors for acceleration, sound, light, and the like. The optical sensor is not particularly limited as long as it can detect light, and for example, a charge coupled device (CCD) image sensor or a complementary metal oxide semiconductor (CMOS) image sensor is used.

As described above, an element region is formed with an element configuration circuit or the like, and an electrode (not shown) is provided to electrically connect the semiconductor chip to the outside. The element region has an electrode region in which an electrode is formed. The electrode of the element region is, for example, a Cu post. The electrode region is basically a region including all formed electrodes. However, in a case where the electrodes are provided discretely, the region where each electrode is provided is also referred to as the electrode region.

A form of the object to be connected may be a form of a single piece such as a semiconductor chip, a form such as a semiconductor wafer, or a form of a wiring layer.

In addition, the anisotropically conductive member is bonded to the object to be connected, but the object to be connected is not particularly limited to the above-described semiconductor element and the like; and for example, a semiconductor element in a wafer state, a semiconductor element in a chip state, a printed wiring board, a heat sink, or the like can be used as the object to be connected.

### ((Semiconductor Element))

In addition to the above, examples of the semiconductor element include a logic large scale integration (logic LSI) (for example, an application specific integrated circuit (ASIC), a field programmable gate array (FPGA), or an application specific standard product (ASSP)), a microprocessor (for example, a central processing unit (CPU) or a graphics processing unit (GPU)), a memory (for example, a dynamic random access memory (DRAM), a hybrid memory cube (HMC), a magnetic memory (magnetic RAM; MRAM), a phase-change memory (PCM), a resistive memory (resistive RAM; ReRAM), a ferroelectric RAM (FeRAM: a ferroelectric memory), or flash memory (not AND (NAND) flash)), a light emitting diode (LED) (for example, a micro flash of a mobile terminal, in-vehicle use, a projector light source, an LCD backlight, or general lighting use),a power device, analog integrated circuit (IC), (for example, a direct current (DC)-direct current (DC) converter, or an insulated gate bipolar transistor (IGBT)), micro electro mechanical systems (MEMS), (for example, an acceleration sensor, a pressure sensor, an oscillator, or a gyro sensor), wireless (for example, a global positioning system (GPS), a frequency modulation (FM), a nearfield communication (NFC), an RF expansion module (RFEM), a monolithic microwave integrated circuit (MMIC), or a wireless local area network (WLAN)), and a discrete element, back side Illumination (BSI), a contact image sensor (CIS), a camera module, a complementary metal oxide semiconductor (CMOS), a passive device, a surface acoustic wave (SAW) filter, a radio frequency (RF) filter, a radio frequency integrated passive device (RFIPD), and broadband (BB).

The semiconductor element is, for example, one complete unit, and the semiconductor element alone exhibits a specific function such as a circuit and a sensor. The semiconductor element may have an interposer function. In addition, for example, it is possible to stack a plurality of devices such as a logic chip having a logic circuit and a memory chip on a device having an interposer function. Furthermore, in this case, even in a case where the electrode size is different for each device, the bonding can be carried out.

### (Example of Method for Manufacturing Anisotropically Conductive Member)

Next, a method for manufacturing the anisotropically conductive member will be described. FIGS. 8 to 14 are schematic cross-sectional views showing an example of the method for manufacturing the anisotropically conductive member according to the embodiment of the present invention in the order of steps. In FIGS. 8 to 14, components having the same constitution as that of the anisotropically conductive member 10 shown in FIGS. 1 to 3 are designated by the same reference numerals, and detailed description thereof will not be repeated.

In one example of the method for manufacturing the anisotropically conductive member, the anisotropically conductive member 10 shown in FIG. 1 will be described with a configuration in which the insulating base material 20 is an aluminum anodized film. An aluminum substrate is used for forming the aluminum anodized film. Therefore, in the example of the method for manufacturing the anisotropically conductive member, first, an aluminum substrate 40 is prepared as shown in FIG. 8.

The size and the thickness of the aluminum substrate 40 are appropriately determined depending on the thickness of the insulating base material 20 (see FIG. 1) in the finally obtained anisotropically conductive member 10 (see FIG. 1), a device for processing, and the like. The aluminum substrate 40 is, for example, a plate material having a circular outer shape. The substrate is not limited to the aluminum substrate, and a metal substrate capable of forming an electrically insulating film can be used. A valve metal capable of forming an anodized film by anodization can be used.

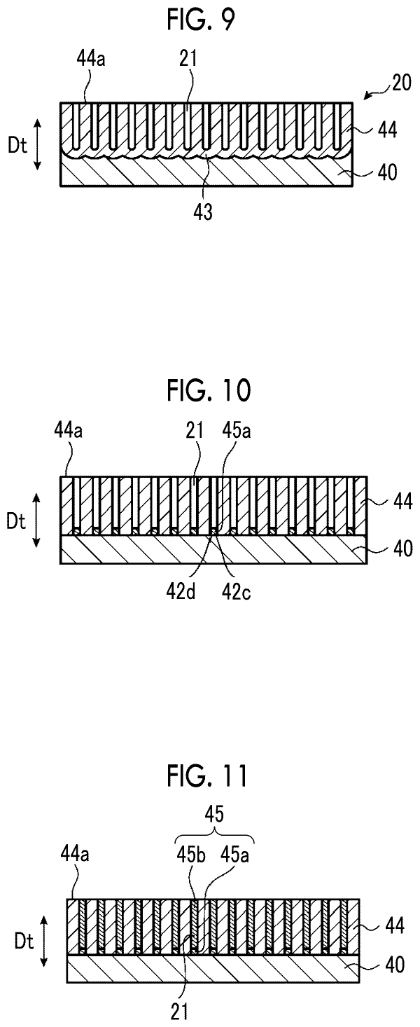

Next, one surface 40a (see FIG. 8) of the aluminum substrate 40 is subjected to an anodization treatment. As a result, one surface 40a (see FIG. 8) of the aluminum substrate 40 is anodized, and as shown in FIG. 9, an anodized film 44 having a plurality of pores 21 extending in the thickness direction Dt of the aluminum substrate 40 is formed.

The anodized film 44 is the above-described insulating base material 20 (see FIG. 1). As shown in FIG. 9, a barrier layer 43 is present at a bottom portion of each pore 21. The above-described anodizing step is referred to as an anodization treatment step.

In the anodized film 44 having the plurality of pores 21, the barrier layer 43 is present at the bottom portion of each pore 21 as described above, and the barrier layer 43 is removed. In this manner, an anodized film 44 (see FIG. 10) having a plurality of pores 21 and no barrier layer 43 is obtained. The above-described step of removing the barrier layer 43 is referred to as a barrier layer removing step.

In the barrier layer removing step, by using an alkaline aqueous solution containing ions of a metal M1 having a higher hydrogen overvoltage than aluminum, the barrier layer 43 of the anodized film 44 is removed, and at the same time, a metal layer 45a (see FIG. 10) consisting of a metal (metal M1) is formed on a surface 42d (see FIG. 10) of a bottom portion 42c (see FIG. 10) of the pores 21. As a result, the aluminum substrate 40 exposed to the pores 21 is coated with the metal layer 45a. In this manner, in a case where the pores 21 are filled with a metal by plating, the plating is likely to proceed and the insufficient filling of the pores 21 with a metal is suppressed, and thus the formation of the conduction path 22 (see FIG. 1) is suppressed.

The above-described alkali aqueous solution containing the ions of the metal M1 may further contain an aluminum ion-containing compound (such as sodium aluminate, aluminum hydroxide, and aluminum oxide). A content of the aluminum ion-containing compound is preferably 0.1 to 20 g/L, more preferably 0.3 to 12 g/L, and still more preferably 0.5 to 6 g/L in terms of the amount of aluminum ions.

Next, the plating is performed from the front surface 44a of the anodized film 44 having a plurality of the pores 21 extending in the thickness direction Dt. In this case, the metal layer 45a can be used as an electrode for the electrolytic plating. In the plating, a metal 45b is used, and the plating proceeds starting from the metal layer 45a formed on the surface 42d (see FIG. 10) of the bottom portion 42c (see FIG. 10) of the pores 21. As a result, as shown in FIG. 11, the inside of the pores 21 of the anodized film 44 is filled with the metal 45b as the conductive substance constituting the conduction path 22. By filling the inside of the pores 21 with the metal 45b, the conduction path 22 having conductivity is formed. The metal layer 45a and the metal 45b are collectively referred to as a metal 45.

The step of filling the plurality of pores 21 of the anodized film 44 with the metal 45b to form the plurality of conduction paths 22 is referred to as a metal filling step. As described above, the conduction path 22 is composed of the conductive substance, and is not limited to being filled with the metal. The electrolytic plating is used in the metal filling step, and the metal filling step will be described in detail later. The front surface 44a of the anodized film 44 corresponds to one surface of the insulating base material 20. The step of filling the plurality of the pores 21 of the anodized film 44 with a conductive substance containing a metal and a substance other than the metal to form the plurality of conduction paths 22 is simply referred to as a filling step.

After the metal filling step, a polishing step of polishing and smoothing the front surface 44a of the anodized film 44 shown in FIG. 11 is performed. For the polishing, for example, a chemical mechanical polishing (CMP) treatment is used.

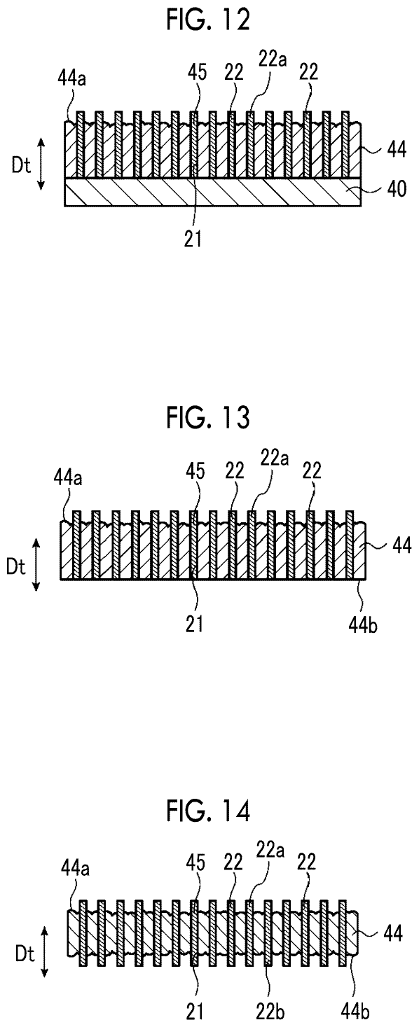

Next, after the polishing step, as shown in FIG. 12, the front surface 44a of the anodized film 44 on the side where the aluminum substrate 40 is not provided is partially removed in the thickness direction Dt, and the metal 45 filled in the metal filling step protrudes from the front surface 44a of the anodized film 44. That is, the conduction path 22 is allowed to protrude from the front surface 44a of the anodized film 44. As a result, the protruding portion 22a is obtained. The step of causing the conduction path 22 to protrude from the front surface 44a of the anodized film 44 is referred to as a front surface protruding step.

In the front surface protruding step, for example, the front surface 44a of the anodized film 44 is dissolved using a solution which dissolves the anodized film 44 without dissolving the metal constituting the conduction path 22. In this case, a spray etching method in which a solution for dissolving is formed into liquid droplets and sprayed onto the front surface 44a of the anodized film 44 is used. In this manner, the front surface 20a of the insulating base material 20 shown in FIG. 3 is obtained.

After the front surface protruding step, the aluminum substrate 40 is removed as shown in FIG. 13. The step of removing the aluminum substrate 40 is referred to as a substrate removing step. In a case of a configuration in which only one protruding portion is provided, a member in a state shown in FIG. 13 can be used as the anisotropically conductive member 10. In this case, the resin layer 24 (see FIG. 1) covering the entire front surface 44a of the anodized film 44, from which the protruding portion 22a protrudes, in the state shown in FIG. 13 is formed to obtain the anisotropically conductive member 10.

Next, as shown in FIG. 13, a polishing step of polishing and smoothing the surface of the anodized film 44 on the side where the aluminum substrate 40 is provided, that is, the back surface 44b of the anodized film 44 is performed after the substrate removing step. For the polishing, for example, a CMP treatment is used.

Next, after the polishing step of the back surface 44b of the anodized film 44, as shown in FIG. 14, a part of the back surface 44b of the anodized film 44 is removed in the thickness direction Dt, and the metal 45 filled in the metal filling step, that is, the conduction path 22 is made to protrude from the back surface 44b of the anodized film 44. As a result, the protruding portion 22b is obtained. The step of causing the conduction path 22 to protrude from the back surface 44b of the anodized film 44 is referred to as a back surface protruding step. The back surface protruding step does not necessarily need to be performed. In a case where the back surface protruding step is not performed, the above-described protruding portion 22b is not formed.

In the back surface protruding step, as in the front surface protruding step, for example, the back surface 44b of the anodized film 44 is dissolved using a solution which dissolves the anodized film 44 without dissolving the metal constituting the conduction path 22. In this case, a spray etching method in which a solution for dissolving is formed into liquid droplets and sprayed onto the back surface 44b of the anodized film 44 is used. In this manner, the back surface 20b of the insulating base material 20 shown in FIG. 3 is obtained as in the front surface 20a.

The above-described front surface protruding step and back surface protruding step may have an aspect in which both steps are performed, or may have an aspect in which one of the front surface protruding step or the back surface protruding step is performed. The front surface protruding step and the back surface protruding step correspond to the “protruding step”, and both the front surface protruding step and the back surface protruding step are the protruding step. The protruding step is also referred to as a trimming step.

In a case where the protruding step is performed, the thickness of the anodized film 44 after the protruding step is the thickness of the insulating base material.

Next, as shown in FIG. 14, the resin layer 24 (see FIG. 1) covering the entire front surface 44a of the anodized film 44, from which the protruding portion 22a protrudes, is formed. In addition, the resin layer 24 (see FIG. 1) covering the entire back surface 44b of the anodized film 44, from which the protruding portion 22b protrudes, is formed. In this manner, the anisotropically conductive member 10 shown in FIG. 1 is manufactured.

### [Anodization Treatment Step]

As the anodization treatment, a known method in the related art can be used, but from the viewpoint of increasing the regularity of the micropore arrangement and ensuring the anisotropic conductivity of the structure, it is preferable to use a self-regulation method or a constant voltage treatment. As a result, for example, the pores and the conduction paths are arranged in a hexagonal shape.

Here, with regard to the self-regulation method or the constant voltage treatment for the anodization treatment, the same treatments as those described in paragraphs [0056] to [0108] and [FIG. 8] of JP2008-270158A can be performed.

### [Holding Step]

In a case of manufacturing the anisotropically conductive member, a holding step may be provided. The holding step is a step of holding a voltage of 95% or more and 105% or less of the holding voltage selected from the range of 1 V or more and less than 30% of the voltage in the above-described anodization treatment step for a total of 5 minutes or more, after the above-described anodization treatment step. In other words, the holding step is a step of performing, after the above-described anodization treatment step, an electrolytic treatment at a voltage of 95% or more and 105% or less of the holding voltage selected from the range of 1 V or more and less than 30% of the voltage in the above-described anodization treatment step for a total of 5 minutes or more.

Here, the “voltage in the anodization treatment” is a voltage applied between the aluminum substrate and the counter electrode; and for example, in a case where the electrolysis time by the anodization treatment is 30 minutes, the “voltage in the anodization treatment” refers to an average value of the voltage maintained for 30 minutes.

From the viewpoint of controlling the thickness of the side wall of the anodized film, that is, the thickness of the barrier layer with respect to the depth of the pores to a proper thickness, the voltage in the holding step is preferably 5% or more and 25% or less and more preferably 5% or more and 20% or less of the voltage in the anodization treatment.

In addition, from the reason that in-plane uniformity is further improved, the total holding time in the holding step is preferably 5 minutes or more and 20 minutes or less, more preferably 5 minutes or more and 15 minutes or less, and still more preferably 5 minutes or more and 10 minutes or less.

In addition, the holding time in the holding step may be a total of 5 minutes or more, but is preferably 5 minutes or more continuously.

Furthermore, the voltage in the holding step may be set to be continuously or stepwise lowered from the voltage in the anodization treatment step to the voltage in the holding step, but from the reason that the in-plane uniformity is further improved, it is preferable to set the voltage to 95% or more and 105% or less of the above-described holding voltage within 1 second after the completion of the anodization treatment step.

The above-described holding step can be performed continuously together with the above-described anodization treatment step by, for example, lowering the electrolytic potential at the end part of the above-described anodization treatment step.

In the above-described holding step, the same electrolytic solution and treatment conditions as those of the above-described conventionally known anodization treatment can be adopted except for the electrolytic potential conditions.

In particular, in a case where the holding step and the anodization treatment step are continuously performed, it is preferable to perform the treatments using the same electrolytic solution.

In the anodized film having a plurality of pores (micropores), the barrier layer (not shown) is present at the bottom portion of the pores as described above. The barrier layer removing step of removing the barrier layer is provided.

### [Barrier Layer Removing Step]

The barrier layer removing step is a step of removing the barrier layer of the anodized film by using, for example, an alkaline aqueous solution containing ions of a metal M1 having a higher hydrogen overvoltage than aluminum.

By the above-described barrier layer removing step, the barrier layer is removed, and a conductor layer consisting of the metal M1 is formed at the bottom portion of the pores.

Here, the hydrogen overvoltage means a voltage required for hydrogen to be generated; and for example, a hydrogen overvoltage of aluminum (Al) is −1.66 V (Journal of the Chemical Society of Japan, 1982, (8), pp. 1305 to 1313). Examples of the metal M1 having a higher hydrogen overvoltage than aluminum and the value of the hydrogen overvoltage thereof are shown below.

<Metal M1 and Hydrogen (1N H₂SO₄) Overvoltage>
Platinum (Pt): 0.00 V
Gold (Au): 0.02 V
Silver (Ag): 0.08 V
Nickel (Ni): 0.21 V
Copper (Cu): 0.23 V
Tin (Sn): 0.53 V
Zinc (Zn): 0.70 V

In the above-described barrier layer removing step, by removing the barrier layer using the alkaline aqueous solution containing ions of the metal M1 having a higher hydrogen overvoltage than aluminum, not only the barrier layer 43 is removed, but also the metal layer 45a of the metal M1, which is less likely to generate hydrogen gas than aluminum, is formed on the aluminum substrate 40 exposed at the bottom portion of the pores 21. As a result, the in-plane uniformity of the metal filling is favorable. It is presumed that the generation of hydrogen gas by the plating liquid is suppressed and thus the metal filling by the electrolytic plating proceeds easily.

In addition, in the barrier layer removing step, in a case where the holding step of holding the voltage of 95% or more and 105% or less of the voltage (the holding voltage) selected from a range of less than 30% of the voltage in the anodization treatment step for a total of 5 minutes or more is provided and the application of the alkali aqueous solution containing ions of the metal M1 is combined, it has been found that the uniformity of the metal filling during the plating treatment is greatly improved. Therefore, it is preferable that the holding step is provided.

Although the detailed mechanism is unknown, it is presumed that, in the barrier layer removing step, a layer of the metal M1 is formed in the lower part of the barrier layer by using the alkali aqueous solution containing ions of the metal M1, whereby damage of an interface between the aluminum substrate and the anodized film can be suppressed, and thus the uniformity of the dissolution of the barrier layer is improved.

In the barrier layer removing step, although the metal layer 45a consisting of a metal (metal M1) is formed at the bottom portion of the pores 21, the present invention is not limited thereto, and only the barrier layer 43 is removed to expose the aluminum substrate 40 at the bottom of the pores 21. The aluminum substrate 40 may be used as an electrode for electrolytic plating in a state in which the aluminum substrate 40 is exposed.

The pores 21 can also be formed by widening the diameter of the micropores and removing the barrier layer. In this case, a pore widening treatment is used for the diameter widening of the micropores. The pore widening treatment is a treatment of dissolving the anodized film by immersing the anodized film in an acid aqueous solution or an alkali aqueous solution to enlarge the pore diameter of the micropores. In the pore widening treatment, an aqueous solution of an inorganic acid such as sulfuric acid, phosphoric acid, nitric acid, and hydrochloric acid, or a mixture thereof, or an aqueous solution of sodium hydroxide, potassium hydroxide, lithium hydroxide, or the like can be used.

In the pore widening treatment, the barrier layer at the bottom portion of the micropores can also be removed, and the micropores are enlarged and the barrier layer is removed by using a sodium hydroxide aqueous solution in the pore widening treatment.

### [Filling Step]

The filling step is a step of filling the pores of the anodized film having a plurality of pores extending in the thickness direction, that is, the insulating base material, with a conductive substance to form a plurality of conduction paths. The conduction path is, for example, a columnar conductor. In a case where the metal is filled in the filling step, it is referred to as a metal filling step.

### <Metal Used in Filling Step>

In the filling step, it is preferable that the metal filled as the conductive substance inside the pores 21 of the anodized film 44 described above in order to form the conduction path is a material having an electrical resistivity of 10³ Ω·cm or less. Specific suitable examples of the above-described metal include gold (Au), silver (Ag), copper (Cu), aluminum (Al), magnesium (Mg), nickel (Ni), zinc (Zn), and cobalt (Co).

From the viewpoint of electrical conductivity and formation by a plating method, as the conductive substance, copper (Cu), gold (Au), aluminum (Al), nickel (Ni), or cobalt (Co) is preferable, copper (Cu) or gold (Au) is more preferable, and copper (Cu) is still more preferable.

### <Plating Method>

As a plating method of filling the inside of the pores 21 with the metal for the anodized film 44 having the plurality of pores 21 extending in the thickness direction Dt, for example, an electrolytic plating method or an electroless plating method can be used.

Here, it is difficult to selectively precipitate (grow) the metal in a hole with a high aspect ratio by an electrolytic plating method known in the related art, which is used for coloration and the like. This is presumed to be because the precipitated metal is consumed in the hole, and thus the plating does not proceed even in a case where electrolysis is carried out for a constant period time or longer.

Therefore, in a case where the metal is filled by the electrolytic plating method, it is necessary to provide a rest time during pulse electrolysis or constant potential electrolysis. A rest time of 10 seconds or longer is required, and the rest time is preferably 30 to 60 seconds.

In addition, it is also desirable to apply ultrasonic waves to promote stirring of the electrolytic solution.

Furthermore, an electrolytic voltage is usually 20 V or less, desirably 10 V or less, but it is preferable that a precipitation potential of a target metal in the electrolytic solution to be used in advance is measured and constant potential electrolysis is performed within the potential +1 V. In a case of performing the constant potential electrolysis, it is desirable that cyclic voltammetry can be used in combination, and a potentiostat device from Solartron Analytical, BAS Inc., HOKUTO DENKO Corporation, IVIUM Technologies B. V., or the like can be used.

### (Plating Liquid)

As a plating liquid, a plating liquid known in the related art can be used. Specifically, a copper sulfate aqueous solution is generally used for precipitating copper, and a concentration of copper sulfate is preferably 1 to 300 g/L and more preferably 100 to 200 g/L. In addition, the precipitation can be promoted by adding hydrochloric acid to the electrolytic solution. In this case, a concentration of hydrochloric acid is preferably 10 to 20 g/L.

In addition, in a case of precipitating gold, it is desirable that a sulfuric acid solution of tetrachloroaurate is used and the plating is performed by alternating current electrolysis. The plating liquid preferably contains a surfactant.

As the surfactant, a known surfactant can be used. Sodium lauryl sulfate, which is known as a surfactant added to the plating liquid in the related art, can also be used as it is. Both ionic (cationic, anionic, or zwitterionic) and nonionic hydrophilic moieties can be used, but a cationic surfactant is desirable from the viewpoint of avoiding the generation of bubbles on the surface of the plating target object. A concentration of the surfactant in the formulation of the plating liquid is desirably 1% by mass or less.

In the electroless plating method, it takes a long time to completely fill the pores consisting of pores having a high aspect ratio with the metal, and thus it is desirable to fill the pores with a metal by the electrolytic plating method.

### [Substrate Removing Step]

The substrate removing step is a step of removing the above-described aluminum substrate after the filling step. The method of removing the aluminum substrate is not particularly limited, and suitable examples thereof include a method of removing the aluminum substrate by dissolution.

### <Dissolution of Aluminum Substrate>

For the above-described dissolution of the aluminum substrate, it is preferable to use a treatment liquid in which the anodized film is difficult to be dissolved but the aluminum is easily dissolved.

In such a treatment liquid, a dissolution rate for the aluminum is preferably 1 μm/min or more, more preferably 3 μm/min or more, and still more preferably 5 μm/min or more. In addition, a dissolution rate for the anodized film is preferably 0.1 nm/min or less, more preferably 0.05 nm/min or less, and still more preferably 0.01 nm/min or less.

Specifically, the treatment liquid is preferably a treatment liquid containing at least one metal compound having an ionization tendency lower than that of aluminum and having a pH of 4 or less or 8 or more. The pH of the treatment liquid is more preferably 3 or less or 9 or more, and still more preferably 2 or less or 10 or more.

The treatment liquid for dissolving the aluminum is preferably a treatment liquid obtained by formulating, for example, a compound of manganese, zinc, chromium, iron, cadmium, cobalt, nickel, tin, lead, antimony, bismuth, copper, mercury, silver, palladium, platinum, or gold (for example, chloroplatinic acid), fluorides of these metals, and chlorides of these metals, based on an acid or alkali aqueous solution.

Among these, an acid aqueous solution-based treatment liquid is preferable, and a chloride-blended treatment liquid is preferable.

In particular, from the viewpoint of treatment latitude, a treatment liquid obtained by blending mercury chloride with a hydrochloric acid aqueous solution (hydrochloric acid/mercuric chloride) or a treatment liquid obtained by blending copper chloride with a hydrochloric acid aqueous solution (hydrochloric acid/copper chloride) is preferable.

The formulation of the treatment liquid for dissolving the aluminum is not particularly limited, and for example, a bromine/methanol mixture, a bromine/ethanol mixture, aqua regia, or the like can be used.

In addition, a concentration of acid or alkali of the treatment liquid for dissolving the aluminum is preferably 0.01 to 10 mol/L and more preferably 0.05 to 5 mol/L.

Furthermore, a treatment temperature in a case of using the treatment liquid for dissolving the aluminum is preferably-10° C. to 80° C. and more preferably 0° C. to 60° C.

In addition, the above-described dissolution of the aluminum substrate is carried out by bringing the aluminum substrate after the above-described plating step into contact with the above-described treatment liquid. A contact method is not particularly limited, and examples thereof include a dipping method and a spraying method. Among these, a dipping method is preferable. A contact time in this case is preferably 10 seconds to 5 hours, and more preferably 1 minute to 3 hours.

In addition, for example, a support base material may be provided in the anodized film 44 in a case of forming the anisotropically conductive member. The support base material preferably has the same outer shape as the anodized film 44. In a case where the support base material is attached, the handleability of the anodized film 44 is improved in a case of forming the anisotropically conductive member.

### [Protruding Step]

The protruding step is a step of causing the conduction path to protrude from at least one of one surface or the other surface of the insulating base material after the polishing step.

Specific examples thereof include removing a part of the above-described anodized film 44. For the removal of a part of the anodized film 44, for example, an acid aqueous solution or an alkali aqueous solution, which does not dissolve the metal constituting the conduction path 22 but dissolves the anodized film 44, that is, aluminum oxide (Al₂O₃), is used. The anodized film 44 is partially removed by bringing liquid droplets of the above-described acid aqueous solution or alkali aqueous solution into contact with the anodized film 44 having the pores 21 filled with the metal. As a method of bringing the above-described acid aqueous solution or alkali aqueous solution into contact with the anodized film 44 in the form of liquid droplets, a spray etching method of spraying the solution for dissolving as described above in the form of liquid droplets onto the insulating base material, that is, the anodized film 44 is used.

In a case where the acid aqueous solution is used, it is preferable to use an aqueous solution of an inorganic acid such as sulfuric acid, phosphoric acid, nitric acid, and hydrochloric acid, or a mixture thereof. Among these, an aqueous solution containing no chromic acid is preferable since it is excellent in safety. A concentration of the acid aqueous solution is preferably 1% to 10% by mass. A temperature of the acid aqueous solution is preferably 25° C. to 60° C.

In addition, in a case where the alkali aqueous solution is used, it is preferable to use at least one alkali aqueous solution selected from the group consisting of sodium hydroxide, potassium hydroxide, and lithium hydroxide. A concentration of the alkali aqueous solution is preferably 0.1% to 5% by mass. A temperature of the alkali aqueous solution is preferably 20° C. to 35° C.

Specifically, for example, a phosphoric acid aqueous solution of 50 g/L and 40° C., a sodium hydroxide aqueous solution of 0.5 g/L and 30° C., or a potassium hydroxide aqueous solution of 0.5 g/L and 30° C. is suitably used.

A dipping time in the acid aqueous solution or the alkali aqueous solution is preferably 8 to 120 minutes, more preferably 10 to 90 minutes, and still more preferably 15 to 60 minutes. Here, the dipping time means the total of each of dipping times in a case where a dipping treatment for a short time is repeated. A washing treatment may be carried out between the dipping treatments.

In addition, the metal 45, that is, the conduction path 22 is allowed to protrude from the front surface 44a or the back surface 44b of the anodized film 44 to a certain extent; but it is preferable that the conduction path 22 protrudes from the front surface 44a or the back surface 44b of the anodized film 44 by 10 nm to 1,000 nm as described above. That is, the above-described length h of the protruding portion 22a in the thickness direction Dt is preferably in a range of 10 nm to 1,000 nm and more preferably in a range of 50 nm to 500 nm since bonding property with the member to be bonded is improved.

In a case where the length h of the protruding portion of the conduction path 22 in the thickness direction Dt are strictly controlled, it is preferable that the inside of the pores 21 is filled with a conductive substance such as a metal, the anodized film 44 and the end part of the conductive substance such as a metal are processed to have the same planar shape, and then the insulating base material such as the anodized film is selectively removed.

In addition, after the filling of the metal or after the protruding step, a heat treatment can be performed for the purpose of reducing the distortion in the conduction path 22 generated in association with the filling of the metal.

From the viewpoint of suppressing oxidation of the metal, the heat treatment is preferably performed in a reducing atmosphere; and specifically, the heat treatment is preferably performed at an oxygen concentration of 20 Pa or less, and more preferably performed under vacuum. Here, the vacuum refers to a state of a space in which at least one of a gas density or an atmospheric pressure is lower than that of the atmosphere.

In addition, it is preferable that the heat treatment is performed while applying a stress to the anodized film 44 for the purpose of correction.

### [Resin Layer Forming Step]

In the step of forming the resin layer 18, for example, an ink jet method, a transfer method, a spraying method, a screen printing method, or the like is used. The ink jet method is preferable since the step of forming the resin layer 18 can be simplified, because the resin layer 18 is directly formed on the insulating base material 20. In addition, the resin layer 18 can be formed using, for example, a known surface protective tape attaching device and a laminator in the related art. In addition, in the step of forming the resin layer, the resin layer is formed on the entire surface of the insulating base material. A resin material constituting the resin layer 18 is as described above.

Examples of the method of forming the resin layer 18 include a method of applying a resin composition containing an antioxidant material, a polymer material, a solvent (for example, methyl ethyl ketone), and the like described later onto the entire surface of the insulating base material, drying the resin composition, and baking the resin composition as necessary, in addition to the above-described method.

A method for applying the resin composition is not particularly limited, and for example, known coating method in the related art, such as a gravure coating method, a reverse coating method, a die coating method, a blade coating method, a roll coating method, an air knife coating method, a screen coating method, a bar coating method, and a curtain coating method, can be used.

In addition, a drying method after the applying is not particularly limited, and examples thereof include a heat treatment at a temperature of 0° C. to 100° C. for several seconds to several tens of minutes in the atmosphere and a heat treatment at a temperature of 0° C. to 80° C. under reduced pressure for ten minutes to several hours.

In addition, a baking method after the drying is not particularly limited since it varies depending on the polymer material to be used; but in a case where a polyimide resin is used, examples thereof include a treatment of heating at a temperature of 160° C. to 240° C. for 2 minutes to 60 minutes, and in a case where an epoxy resin is used, examples thereof include a treatment of heating at a temperature of 30° C. to 80° C. for 2 minutes to 60 minutes.

The present invention is basically configured as described above. The anisotropically conductive member and bonded body according to the embodiments of the present invention has been described in detail above, but the present invention is not limited to the above-described embodiments, and various improvements and changes can be made without departing from the spirit of the present invention.

### EXAMPLES

Hereinafter, the characteristics of the present invention will be described in detail by Examples. The materials, reagents, amounts and proportions of substances, operations, and the like described in the following examples can be appropriately modified as long as the gist of the present invention is maintained. Therefore, the scope of the present invention is not limited to Examples shown below.

In the present example, bonded bodies of Examples 1 to 12 and bonded bodies of Comparative Examples 1 and 2 were produced. The sizes and the like of the bonded bodies of Examples 1 to 12 and the bonded bodies of Comparative Examples 1 and 2 are shown in Table 1 below.

The bonding strength and the state of the protruding portion after bonding were evaluated for the bonded bodies of Examples 1 to 12 and the bonded bodies of Comparative Examples 1 and 2. The bonding strength and the evaluation results of the state of the protruding portion after bonding are shown in Table 2 below.

Next, the bonding strength and the state of the protruding portion after bonding will be described.

### (Evaluation of Bonding Strength)

The bonding strength was evaluated by measuring a shear strength of the bonded body of the TEG chip, the anisotropically conductive member, and the interposer of each of Examples and Comparative Examples using Stellar 4000 bond tester (manufactured by Nordson Corporation).

The bonding strength was obtained by obtaining a bonding strength value (MPa) per area of the TEG chip from the obtained destructive load. The bonding strength value was evaluated according to the following evaluation standard. The evaluation results are shown in the column of the bonding strength in Table 2.

### Evaluation Standard

A: 10 MPa≤bonding strength value
B: 3 MPa≤bonding strength value<10 MPa
C: bonding strength value<3 MPa

### <Production of Bonded Body for Evaluation>

A test element group (TEG) chip having a Cu pad and an interposer were prepared. The insulating layer was SiN. A level difference between the insulating layer and the Cu pad surface was 1 μm. As the TEG chip, a TEG chip having a chip size of 8 mm square and a ratio of an electrode area (copper post) to a chip area of 25% was prepared. Since the interposer included a lead-out wiring line in the periphery thereof, a chip having a size of a 10 mm square was prepared. A 10 mm-square anisotropically conductive member was used.

In the bonding, the TEG chip, the anisotropically conductive member, and the interposer were laminated in this order, and a temporary bonding was carried out using a normal temperature bonding device (WP-100 (model), manufactured by PMT Corporation) under the conditions of a temporary bonding process at a heating temperature of 80° C., a time of 1 minute, and a pressure of 10 MPa.

Next, the temporarily bonded sample was main-bonded using a normal temperature bonding device (WP-100 (model), manufactured by PMT Corporation) under a pressurization condition of a pressure of 10 MPa, and then bonded under conditions of a heating temperature of 140° C. and a time of 10 seconds.

Next, for the main-bonded sample, the resin layer was cured under the conditions of a resin curing process at a heating temperature of 250° C., 180 seconds, and a pressure of 10 MPa, thereby producing a bonded body for evaluation.

A laminate in which the TEG chip, the anisotropically conductive member, and the interposer were laminated in this order was defined as a type 1 laminate configuration.

In addition, the TEG chip, the anisotropically conductive member, the TEG chip, the anisotropically conductive member, and the interposer were laminated in this order, and a temporary bonding was carried out using the above-described normal temperature bonding device (WP-100 (model), manufactured by PMT Corporation) under the conditions of a temporary bonding process at a heating temperature of 80° C., a time of 1 minute, and a pressure of 10 MPa.

Next, the temporarily bonded sample was main-bonded using a normal temperature bonding device (WP-100 (model), manufactured by PMT Corporation) under a pressurization condition of a pressure of 10 MPa, and then bonded under conditions of a heating temperature of 140° C. and a time of 10 seconds. Next, for the main-bonded sample, the resin layer was cured under the conditions of a resin curing process at a heating temperature of 250° C., 180 seconds, and a pressure of 10 MPa, thereby producing a bonded body for evaluation.

A laminate in which the TEG chip, the anisotropically conductive member, the TEG chip, the anisotropically conductive member, and the interposer were laminated in this order was defined as a type 2 laminate configuration.

### (State of Protruding Portion After Bonding)

The state of the protruding portion after bonding will be described.

The anodized film of the bonded body of the TEG chip, the anisotropically conductive member, and the interposer of each of Examples and Comparative Examples was machined in the thickness direction using a focused ion beam (FIB).

Next, an image with a magnification of 100,000 times was acquired using a field emission scanning electron microscope (S-4800 (model) manufactured by Hitachi High-Tech Corporation).

In the acquired captured image, 100 portions corresponding to the protruding portions were specified. For the 100 specified protruding portions, the presence or absence of contact of adjacent protruding portions was determined. For the 100 specified protruding portions, the state of the protruding portions after bonding was evaluated according to the following evaluation standard based on the presence or absence of contact of adjacent protruding portions. The evaluation results are shown in the column of the state of the protruding portion after bonding in Table 1. The state of the protruding portion after bonding is an indicator for evaluating the degree of buckling of the protruding portion.

### Evaluation Standard

A: number of protruding portions in contact with adjacent protruding portion among the 100 protruding portions was 0.
B: number of protruding portions in contact with adjacent protruding portion among the 100 protruding portions was 1 or more and 10 or less.
C: number of protruding portions in contact with adjacent protruding portion among the 100 protruding portions was 11 or more.

In a case where the protruding portion was in contact with the adjacent protruding portion even partially, it was determined that the protruding portion was in contact with the adjacent protruding portion.

Next, Examples 1 to 12 and Comparative Examples 1 and 2 will be described.

### Example 1

A bonded body of Example 1 will be described. In Example 1, an aluminum anodized film was used as an insulating base material.

### [Structure]

### <Production of Aluminum Substrate>

A molten metal was produced using an aluminum alloy containing 0.06% by mass of Si, 0.30% by mass of Fe, 0.005% by mass of Cu, 0.001% by mass of Mn, 0.001% by mass of Mg, 0.001% by mass of Zn, and 0.03% by mass of Ti and, as the remainder, Al and unavoidable impurities, a molten metal treatment and filtration were performed, and an ingot having a thickness of 500 mm and a width of 1,200 mm was produced according to a direct chill (DC) casting method.

Next, the surface was scraped off using a surface grinder having an average thickness of 10 mm and heated at 550° C. and maintained the state for approximately 5 hours. After the temperature was decreased to 400° C., a rolled sheet having a thickness of 2.7 mm was obtained using a hot rolling mill.

Furthermore, the rolled plate was subjected to a heat treatment at 500° C. using a continuous annealing machine, and then subjected to cold rolling to be finished to a thickness of 1.0 mm, thereby obtaining an aluminum substrate in accordance to JIS 1050 Material.

The aluminum substrate was formed into a wafer shape with a diameter of 200 mm (8 inches), and then subjected to each of the following treatments.

### <Electropolishing Treatment>

The above-described aluminum substrate was subjected to an electropolishing treatment using an electropolishing liquid having the following formulation under conditions of a voltage of 25 V, a liquid temperature of 65° C., and a liquid flow rate of 3.0 m/min.

A carbon electrode was used as a cathode, and GP0110-30R (manufactured by TAKASAGO Ltd.) was used as a power source. In addition, the flow rate of the electrolytic solution was measured using a vortex flow monitor FLM22-10PCW (manufactured by AS ONE Corporation).

### (Formulation of Electropolishing Liquid)

| | | |
|---|---|---|
| 85% by mass of phosphoric acid (reagent manufactured | 660 | mL |
| by FUJIFILM Wako Pure Chemical Corporation) | | |
| Pure water | 160 | mL |
| Sulfuric acid | 150 | mL |
| Ethylene glycol | 30 | mL |

### <Anodization Treatment Step>

Next, the aluminum substrate after the electropolishing treatment was subjected to an anodization treatment by a self-ordering method according to the procedure described in JP2007-204802A.

The aluminum substrate after the electropolishing treatment was subjected to a pre-anodization treatment for 5 hours using an electrolytic solution of 0.50 mol/L oxalic acid under conditions of a voltage of 40 V, a liquid temperature of 16° C., and a liquid flow rate of 3.0 m/min.

Thereafter, the aluminum substrate subjected to the pre-anodization treatment was dipped for 12 hours in a mixed aqueous solution (liquid temperature: 50° C.) of 0.2 mol/L of chromic acid anhydride and 0.6 mol/L phosphoric acid to perform a film removal treatment.

Thereafter, the aluminum substrate was subjected to a re-anodization treatment for 10 hours using an electrolytic solution of 0.50 mol/L oxalic acid under conditions of a voltage of 40 V, a liquid temperature of 16° C., and a liquid flow rate of 3.0 m/min to obtain an anodized film having a film thickness of 80 μm.

In the pre-anodization treatment and the re-anodization treatment, a stainless steel electrode was used as a cathode, and GP0110-30R (manufactured by TAKASAGO Ltd.) was used as a power source. In addition, NeoCool BD36 (manufactured by Yamato Scientific Co., Ltd.) was used as a cooling device, and PAIRSTIRRER PS-100 (manufactured by TOKYO RIKAKIKAI CO., LTD.) was used as a stirring and heating device. Furthermore, the flow rate of the electrolytic solution was measured using a vortex flow monitor FLM22-10PCW (manufactured by AS ONE Corporation).

### <Barrier Layer Removing Step>

Next, an electrolytic treatment (electrolytic removal treatment) was carried out while continuously lowering the voltage from 40 V to 0 V at a voltage lowering rate of 0.2 V/sec under the same treatment liquid and treatment conditions as those of the above-described anodization treatment.

Thereafter, an etching treatment (etching removal treatment) of dipping in 5% by mass phosphoric acid at 30° C. for 30 minutes was carried out to remove the barrier layer in the bottom portion of the micropores of the anodized film, and the aluminum substrate was exposed through the micropores.

Here, an average opening diameter of the micropores present in the anodized film after the barrier layer removing step was 60 nm. The average opening diameter was obtained by acquiring a surface image at a magnification of 50,000 times using a field emission scanning electron microscope (FE-SEM), selecting 50 micropores in the surface image, and measuring diameters of portions corresponding to the opening for each of the selected 50 micropores. An average value of the diameters of the portions corresponding to the openings of the measured micropores was calculated. The average value was defined as the average opening diameter.

In addition, an average thickness of the anodized film after the barrier layer removing step was 80 μm. For the average thickness, the anodized film was machined in the thickness direction using a focused ion beam (FIB), and an image of a cross section thereof was acquired at a magnification of 50,000 times with a field emission scanning electron microscope (FE-SEM). In the cross-sectional image, lengths of 10 portions corresponding to the thickness of the anodized film were measured, and an average value of the lengths of the 10 measured portions was obtained. The average value was defined as the average thickness of the anodized film after the barrier layer removing step.

In addition, a density of the micropores present in the anodized film was approximately 100 million/mm². The density of the micropores was measured and calculated by a method described in paragraphs and of JP2008-270158A.

In addition, a degree of regularity of the micropores present in the anodized film was 92%. The degree of regularity was measured and calculated by acquiring a surface image at a magnification of 20,000 times using a field emission scanning electron microscope (FE-SEM)

by a method described in paragraphs to of JP2008-270158A.

### <Metal Filling Step>

Next, the aluminum substrate was used as a cathode, and platinum was used as a positive electrode for an electrolytic plating treatment.

Specifically, a copper plating liquid having the following formulation was used, and by carrying out electrolytic plating under constant current, a metal-filled microstructure in which the inside of the pores (micropores) was filled with copper to form a conduction path was produced.

Here, for the constant current electrolysis, a plating device manufactured by YAMAMOTO-MS Co., Ltd. was used, and a power source (HZ-3000) manufactured by

HOKUTO DENKO Corporation was used, cyclic voltammetry was carried out in the plating liquid, and then after checking precipitation potential, the treatment was carried out under the conditions shown below.

### (Formulation and Conditions of Copper Plating Liquid)

| | | |
|---|---|---|
| Copper sulfate | 100 | g/L |
| Sulfuric acid | 50 | g/L |
| Hydrochloric acid | 15 | g/L |
| Temperature | 25° | C. |
| Current density | 10 | A/dm² |

### <Polishing Step>

Next, the front surface of the metal-filled microstructure in which the conduction path filled with the metal was formed was subjected to a CMP treatment, and polished by 5 μm from the surface to smoothen the surface. As a CMP slurry, PNANERLITE-7000 manufactured by Fujimi Incorporated. was used.

The front surface of the anodized film after filling the pores (micropores) with the metal was observed with a field emission scanning electron microscope (FE-SEM), and in a case where the presence or absence of sealing with metal in 1,000 micropores was observed to calculate a sealing rate (the number of micropores to be sealed/1000), it was 96%.

In addition, in a case where the anodized film after filling the pores (micropores) with the metal was machined with FIB in the thickness direction and an image of a cross section was acquired at a magnification of 50,000 times with a field emission scanning electron microscope (FE-SEM) to confirm the inside of the micropores, it was confirmed that the inside of the sealed pores (micropores) was completely filled with the metal.

### <Trimming Step>

By a spray etching method, a sodium hydroxide aqueous solution (concentration: 5% by mass, liquid temperature: 20° C.) was sprayed in the form of liquid droplets onto the surface of the anodized film of the metal-filled microstructure after the polishing step. The amount of the sodium hydroxide aqueous solution sprayed was adjusted so that the above-described arithmetic mean distance δ (see FIG. 3) in the thickness direction was 100 nm, and the surface of the aluminum anodized film was selectively dissolved, and then washed with water and dried to protrude a copper column as a conduction path. As a result, the above-described length h (see FIG. 1) of the protruding portion was 300 nm.

As the spray etching method, ADE-3000S (product name) manufactured by Actis Kyoso Co., Ltd. was used.

The above-described arithmetic mean distance δ (see FIG. 3) in the thickness direction on the front surface side of the anodized film was measured using the captured image as described above.

### <Substrate Removing Step>

Next, the aluminum substrate was dipped in a 20% by mass mercury chloride aqueous solution (mercury vapor) at 20° C. for 3 hours to dissolve and remove the aluminum substrate, thereby producing a structure.

### <Polishing Step>

Next, the back surface of the anodized film formed by removing the aluminum substrate of the structure was subjected to a CMP treatment to smooth the metal-filled microstructure. As a CMP slurry, PNANERLITE-7000 manufactured by Fujimi Incorporated. was used.

### <Trimming Step>

After the polishing step, a sodium hydroxide aqueous solution (concentration: 5% by mass, liquid temperature: 20° C.) was sprayed in the form of liquid droplets onto the back surface of the anodized film of the structure by a spray etching method. The amount of the sodium hydroxide aqueous solution sprayed was adjusted so that the above-described arithmetic mean distance δ (see FIG. 3) in the thickness direction was 100 nm, and the surface of the aluminum anodized film was selectively dissolved, and then washed with water and dried to protrude a copper column as a conduction path. As a result, the above-described length h (see FIG. 1) of the protruding portion was 300 nm.

As the spray etching method, ADE-3000S (product name) manufactured by Actis Kyoso Co., Ltd. was used.

The above-described arithmetic mean distance δ in the thickness direction on the back surface side of the anodized film was measured using the captured image as described above.

### <Resin Layer Forming Step>

A resin layer was formed on the front surface and the back surface of the anodized film with respect to the structure after the trimming step by a method shown below, thereby producing an anisotropically conductive member.

The resin layer was formed by using a resin composition containing a non-conductive epoxy-based thermosetting resin (BST001A, curing temperature: 150° C., manufactured by NAMICS CORPORATION) and diethylene glycol diethyl ether as a diluent solvent, while adjusting a rotation speed of a spin coater such that a thickness was set to 1.5 μm.

Next, the produced anisotropically conductive member was cut into a size of 10 mm square. DAD3230 (product name) manufactured by DISCO Corporation was used for cutting the anisotropically conductive member.

The above-described arithmetic mean distance δ was obtained as follows.

The cross section of the anodized film as the insulating base material in the thickness direction was exposed by machining the produced anisotropically conductive member using a focused ion beam (FIB).

Next, for the cross section of the anodized film in the thickness direction, an image was acquired at a magnification of 150k using a field emission scanning electron microscope (FE-SEM).

In the captured image, the reference point Pb (see FIG. 3) was set at any position on the back surface 20b side of the insulating base material 20, opposite to the front surface 20a. The reference line Ls (see FIG. 3) parallel to the direction x passing through the reference point Pb was set.

Next, in the captured image, 10 apex portions Pc (see FIG. 3) were selected in descending order from the reference line Ls among the points corresponding to the apex portions Pc. In addition, among the points corresponding to the contact portions Vc, 10 contact portions Vc (see FIG. 3) were selected in ascending order from the reference line Ls.

In the captured image, a distance from the reference line Ls was obtained for each of the 10 selected points corresponding to the apex portions Pc. An average value of the 10 distances between the 10 points corresponding to the apex portions Pc and the reference line Ls was obtained by the least squares method. The average value obtained by the least squares method was shown as a point on the captured image. The line Lc (see FIG. 3) parallel to the direction x passing through a point indicating the average value of the apex portion Pc was obtained.

In the captured image, a distance from the reference line Ls was obtained for each of the 10 selected points corresponding to the contact portions Vc. An average value of the 10 distances between the 10 points corresponding to the contact portions Vc and the reference line Ls was obtained by the least squares method. The average value obtained by the least squares method was shown as a point on the captured image. The line Lb (see FIG. 3) parallel to the direction x passing through a point indicating the average value of the contact portion Vc was obtained.

Next, the arithmetic mean distance δ was obtained by obtaining the distance between the parallel line Lc and the parallel line Lb in the thickness direction Dt.

### Example 2

Example 2 is different from Example 1 in that the amount of the sodium hydroxide aqueous solution sprayed is adjusted such that the above-described arithmetic mean distance δ (see FIG. 3) in the thickness direction was 20 nm on both the front surface side and the back surface side of the anodized film, and thus the front surface and the back surface of the aluminum anodized film were selectively dissolved. The other conditions were the same as those in Example 1.

### Example 3

Example 3 is different from Example 1 in that the amount of the sodium hydroxide aqueous solution sprayed is adjusted such that the above-described arithmetic mean distance δ (see FIG. 3) in the thickness direction was 60 nm on both the front surface side and the back surface side of the anodized film, and thus the front surface and the back surface of the aluminum anodized film were selectively dissolved. The other conditions were the same as those in Example 1.

### Example 4

Example 4 is different from Example 1 in that the amount of the sodium hydroxide aqueous solution sprayed is adjusted such that the above-described arithmetic mean distance δ (see FIG. 3) in the thickness direction was 5 nm on both the front surface side and the back surface side of the anodized film, and thus the front surface and the back surface of the aluminum anodized film were selectively dissolved. The other conditions were the same as those in Example 1.

### Example 5

Example 5 is different from Example 3 in that the resin was on the CNP surface, and other points are the same as in Example 2. The resin being present on the CNP surface means a state in which the epoxy resin was applied onto the protruding portion of the anisotropically conductive member.

### Example 6

Example 6 is different from Example 3 in that the resin was on the electrode surface, and other points are the same as in Example 2. The resin being present on the electrode surface means a state in which the epoxy resin was applied onto the Cu pad surface of the TEG chip.

### Example 7

Example 7 is different from Example 2 in that the conduction path was composed of Ni, and other points are the same as in Example 2.

The conduction path was formed by an electrolytic plating treatment using a mixed solution of nickel sulfate/nickel chloride/boric acid=300/60/40 (g/L) in an electrolytic solution, using a nickel electrode as a cathode and a platinum electrode as a positive electrode. In the electrolytic plating treatment, constant current electrolysis (5 A/dm²) was carried out while maintaining the electrolytic solution at a temperature of 50° C.

### Example 8

Example 8 is different from Example 2 in that the above-described length h (see FIG. 1) of the protruding portion was set to 10,000 nm, and other points are the same as in Example 2.

### Example 9

Example 9 is different from Example 2 in that the above-described length h (see FIG. 1) of the protruding portion was set to 3 nm, and other points are the same as in Example 2.

### Example 10

Example 10 is different from Example 3 in that the size of the TEG chip was set to 4 mm square, and other points are the same as in Example 3.

### Example 11

Example 11 is different from Example 3 in that the size of the anisotropically conductive member was set to 8 mm square, and other points are the same as in Example 3.

### Example 12

Example 12 is different from Example 3 in that the type 2 laminate configuration in which the TEG chip, the anisotropically conductive member, the TEG chip, the anisotropically conductive member, and the interposer were laminated in this order was used, and the size of the anisotropically conductive member was set to 8 mm square, and other points are the same as in Example 3.

### Comparative Example 1

Comparative Example 1 is different from Example 1 in that any of the above-described trimming steps was carried out by a dipping method instead of the spray etching method.

Furthermore, in Comparative Example 1, the temporarily bonded sample was main-bonded using a normal temperature bonding device (WP-100 (model), manufactured by PMT Corporation) under a pressurization condition of a pressure of 10 MPa, and then bonded under conditions of a heating temperature of 120° C. and a time of 10 seconds. The other conditions were the same as those in Example 1.

In Comparative Example 1, the above-described arithmetic mean distance δ (see FIG. 3) in the thickness direction was set to 1 nm.

### Comparative Example 2

Comparative Example 2 is different from Example 1 in that the amount of the sodium hydroxide aqueous solution sprayed is adjusted such that the above-described arithmetic mean distance δ (see FIG. 3) in the thickness direction was 250 nm on both the front surface side and the back surface side of the anodized film, and thus the front surface and the back surface of the aluminum anodized film were selectively dissolved. The other conditions were the same as those in Example 1.

TABLE 1

| | | | | | | | Size (mm × mm) | | | | Arithmetic |
|---|---|---|---|---|---|---|---|---|---|---|---|
| | | Material of | Epoxy | | Protruding | Number | | | Anisotropically | | mean |
| | Trimming | conduction | sealing | Aspect | length | of chips | TEG | | conductive | Laminate | distance δ |
| | step | path | material | ratio | (nm) | (number) | chip | Interposer | member | configuration | (nm) |
| Example 1 | Spray | Cu | None | 0.2 | 300 | 1 | 8 | 10 | 10 | | 100 |
| | etching | | | | | | | | | | |
| | method | | | | | | | | | | |
| Example 2 | Spray | Cu | None | 0.2 | 300 | 1 | 8 | 10 | 10 | | 20 |
| | etching | | | | | | | | | | |
| | method | | | | | | | | | | |
| Example 3 | Spray | Cu | None | 0.2 | 300 | 1 | 8 | 10 | 10 | | 60 |
| | etching | | | | | | | | | | |
| | method | | | | | | | | | | |
| Example 4 | Spray | Cu | None | 0.2 | 300 | 1 | 8 | 10 | 10 | | 5 |
| | etching | | | | | | | | | | |
| | method | | | | | | | | | | |
| Example 5 | Spray | Cu | CNP | 0.2 | 300 | 1 | 8 | 10 | 10 | | 60 |
| | etching | | surface | | | | | | | | |
| | method | | | | | | | | | | |
| Example 6 | Spray | Cu | Electrode | 0.2 | 300 | 1 | 8 | 10 | 10 | | 60 |
| | etching | | surface | | | | | | | | |
| | method | | | | | | | | | | |
| Example 7 | Spray | Ni | None | 0.2 | 300 | 1 | 8 | 10 | 10 | | 20 |
| | etching | | | | | | | | | | |
| | method | | | | | | | | | | |
| Example 8 | Spray | Cu | None | 0.006 | 10000 | 1 | 8 | 10 | 10 | | 20 |
| | etching | | | | | | | | | | |
| | method | | | | | | | | | | |
| Example 9 | Spray | Cu | None | 20 | 3 | 1 | 8 | 10 | 10 | | 20 |
| | etching | | | | | | | | | | |
| | method | | | | | | | | | | |
| Example 10 | Spray | Cu | None | 0.2 | 300 | 1 | 4 | 10 | 10 | | 60 |
| | etching | | | | | | | | | | |
| | method | | | | | | | | | | |
| Example 11 | Spray | Cu | None | 0.2 | 300 | 1 | 8 | 10 | 8 | | 60 |
| | etching | | | | | | | | | | |
| | method | | | | | | | | | | |
| Example 12 | Spray | Cu | None | 0.2 | 300 | 2 | 8 | 10 | 8 | | 60 |
| | etching | | | | | | | | | | |
| | method | | | | | | | | | | |
| Comparative | Dipping | Cu | None | 0.2 | 300 | 1 | 8 | 10 | 10 | | 1 |
| Example 1 | method | | | | | | | | | | |
| Comparative | Spray | Cu | None | 0.2 | 300 | 1 | 8 | 10 | 10 | | 250 |
| Example 2 | etching | | | | | | | | | | |
| | method | | | | | | | | | | |

TABLE 2

| | Temporary bonding process | | | Main bonding process | | | Resin curing process | | | | State of |
|---|---|---|---|---|---|---|---|---|---|---|---|
| | Heating | | | Heating | | | Heating | | | | protruding |
| | temperature | Pressure | Time | temperature | Pressure | Time | temperature | Pressure | Time | Bonding | portion after |
| | (° C.) | (MPa) | (sec) | (° C.) | (MPa) | (sec) | (° C.) | (MPa) | (sec) | strength | bonding |
| Example 1 | 80 | 10 | 60 | 140 | 10 | 10 | 250 | 10 | 180 | A | B |
| Example 2 | 80 | 10 | 60 | 140 | 10 | 10 | 250 | 10 | 180 | A | A |
| Example 3 | 80 | 10 | 60 | 140 | 10 | 10 | 250 | 10 | 180 | A | A |
| Example 4 | 80 | 10 | 60 | 140 | 10 | 10 | 250 | 10 | 180 | B | B |
| Example 5 | 80 | 10 | 60 | 140 | 10 | 10 | 250 | 10 | 180 | A | A |
| Example 6 | 80 | 10 | 60 | 140 | 10 | 10 | 250 | 10 | 180 | A | A |
| Example 7 | 80 | 10 | 60 | 140 | 10 | 10 | 250 | 10 | 180 | B | B |
| Example 8 | 80 | 10 | 60 | 140 | 10 | 10 | 250 | 10 | 180 | B | B |
| Example 9 | 80 | 10 | 60 | 140 | 10 | 10 | 250 | 10 | 180 | B | B |
| Example 10 | 80 | 10 | 60 | 140 | 10 | 10 | 250 | 10 | 180 | A | A |
| Example 11 | 80 | 10 | 60 | 140 | 10 | 10 | 250 | 10 | 180 | A | A |
| Example 12 | 80 | 10 | 60 | 140 | 10 | 10 | 250 | 10 | 180 | A | A |
| Comparative | 80 | 10 | 60 | 120 | 10 | 10 | 250 | 10 | 180 | C | C |
| Example 1 | | | | | | | | | | | |
| Comparative | 80 | 10 | 60 | 140 | 10 | 10 | 250 | 10 | 180 | B | C |
| Example 2 | | | | | | | | | | | |

As shown in Table 2, Examples 1 to 12 had a favorable bonding strength and a favorable state of the protruding portion after bonding, as compared with Comparative Examples 1 and 2.

In Comparative Example 1, the arithmetic mean distance δ was short, the bonding strength was low, and the number of protruding portions in contact with adjacent protruding portion was large.

In Comparative Example 2, the arithmetic mean distance δ was large, and the number of protruding portions in contact with adjacent protruding portion was large.

From Examples 1 to 12, the bonding strength and the state of the protruding portion after bonding were more excellent in Examples 2, 3, 5, 6, 10, and 11

From Examples 1 to 4, it was found that the bonding strength and the state of the protruding portion after bonding were more excellent in a case where the arithmetic mean distance δ was 20 to 100 nm, and the bonding strength and the state of the protruding portion after bonding were further excellent in a case where the arithmetic mean distance δ was 20 to 60 nm.

From Examples 2 and 7, it was found that the bonding strength and the state of the protruding portion after bonding were more excellent in a case where the conduction path was made of Cu, instead of Ni.

From Example 2, Example 8, and Example 9, it was found that Example 2 in which the protruding portion was 300 nm was more excellent in the bonding strength and the state of the protruding portion after bonding.

### EXPLANATION OF REFERENCES

10: anisotropically conductive member
12, 13: bonded body
18: resin layer
20: insulating base material
20a, 24a, 40a, 32a, 34a, 37a, 44a: front surface
20b, 44b: back surface
20d: recessed portion
21: pore
22: conduction path
22a, 22b: protruding portion
22c: side surface
24: resin layer
30, 31: semiconductor element
32, 37: element substrate
33: resin layer
34, 35, 38: electrode
36, 39: insulating layer
40: aluminum substrate
42c: bottom portion
42d: surface
43: barrier layer
44: anodized film
45, 45b: metal
45a: metal layer
Dt: thickness direction
Ls: reference line
Pb: reference point
Pc: apex portion
Vc: contact portion
d: average diameter
hm: average thickness
ht: thickness
p: center-to-center distance
x: direction
δ: arithmetic mean distance
w: interval

What is claimed is:

1. An anisotropically conductive member comprising:
an insulating base material having electrical insulating properties; and
a plurality of conduction paths that penetrate in a thickness direction of the insulating base material, are provided in a state of being electrically insulated from each other, and have a protruding portion which protrudes from at least one surface of the insulating base material,
wherein, in a cross section of the insulating base material in the thickness direction, the surface of the insulating base material, from which the protruding portion of the conduction path protrudes, has a plurality of apex portions and a plurality of contact portions in which a plurality of protruding portions are in contact with the insulating base material,
an arithmetic mean distance between the plurality of contact portions and the plurality of apex portions in the thickness direction is 2 nm to 200 nm,
the conduction path is composed of Cu, Au, or Al,
in a case where a diameter of the protruding portion is denoted by d and a length of the protruding portion in the thickness direction of the insulating base material is denoted by h, d/h is 0.1 to 20, and
a length of the protruding portion in the thickness direction of the insulating base material is 6 to 6,000 nm.

2. A bonded body comprising:
an anisotropically conductive member; and
a member to be bonded,
wherein the anisotropically conductive member and the member to be bonded are bonded to each other,
a resin fills a space between the anisotropically conductive member and the member to be bonded,
the anisotropically conductive member includes
an insulating base material having electrical insulating properties, and
a plurality of conduction paths that penetrate in a thickness direction of the insulating base material, are provided in a state of being electrically insulated from each other, and have a protruding portion which protrudes from at least one surface of the insulating base material,
in a cross section of the insulating base material in the thickness direction, the surface of the insulating base material, from which the protruding portion of the conduction path protrudes, has a plurality of apex portions and a plurality of contact portions in which a plurality of protruding portions are in contact with the insulating base material,
an arithmetic mean distance between the plurality of contact portions and the plurality of apex portions in the thickness direction is 2 nm to 200 nm,
the conduction path is composed of Cu, Au, or Al,
in a case where a diameter of the protruding portion is denoted by d and a length of the protruding portion in the thickness direction of the insulating base material is denoted by h, d/h is 0.1 to 20, and
a length of the protruding portion in the thickness direction of the insulating base material is 6 to 6,000 nm.

3. The bonded body according to claim 2,
wherein the member to be bonded has a metal layer and a resin layer, and the metal layer is exposed from the resin layer.

4. The bonded body according to claim 3,
wherein the member to be bonded has a plurality of metal layers, and at least one of the plurality of metal layers has a different height.

5. The bonded body according to claim 3,
wherein the member to be bonded has a bonding surface provided with a plurality of metal layers, and an area of the bonding surface is larger than an area of the surface of the anisotropically conductive member, from which the protruding portion protrudes.
